(19) United States
(12) Patent Application Publication
(10) Pub. No.: US 2005/0220186 A1
(43) Pub. Date: Oct. 6, 2005

(54) Timing adjustment method and digital filter and receiver using the method

(76) Inventor: Tadahisa Kohyama, Gifu-City (JP)

Correspondence Address: MCDERMOTT WILL & EMERY LLP, 600 13TH STREET, N.W., WASHINGTON, DC, 20005-3096, US

(21) Appl. No.: 11/093,022

(22) Filed: Mar. 30, 2005

(30) Foreign Application Priority Data
Mar. 30, 2004 (JP) 2004-101438
Mar. 16, 2005 (JP) 2005-074552

(51) Int. Cl. H03K 5/159

(52) U.S. Cl. 375/232

(57) ABSTRACT

A delay unit comprises a plurality of taps for sequentially delaying an input digital received signal. A shift unit changes combinations of a plurality of digital received signals delayed by the delay unit and a multiplier unit. A coefficient retaining unit manages a plurality of coefficients to be multiplied by the plurality of digital received signals delayed by the delay unit. A selector unit 352 selects one of the coefficients retained in the coefficient retaining unit in accordance with an instruction from a control unit. The multiplier unit multiplies the plurality of digital received signals delayed by the delay unit by the coefficient selected by the selector unit. An adder adds up results of multiplication by the multiplier unit and outputs a result of addition as a filter output signal.

### BACKGROUND OF THE INVENTION

1. Field of the Invention

The present invention relates to a timing adjustment technology and, more particularly, to a timing adjustment method for adjusting the timing of an input signal and outputting the time-adjusted signal. The invention further relates to a digital filter and a receiver using the method.

2. Description of the Related Art

Wireless local area network (LAN) that complies with the IEEE 802.11b standard is practiced as a spread spectrum communications system using a radio frequency of 2.4 GHz band. The IEEE 802.11b wireless LAN enables a maximum transmission rate of 11 Mbps using complementary code keying (CCK). In a receiver adapted for CCK modulation, a plurality of waveform patterns for a transmitted signal are generally prepared. A combination of signals having a waveform that best matches the waveform of the received signal is defined as a demodulation result (See reference (1) in the following Related Art List, for instance). The spread spectrum system employed in wireless LAN that complies with the IEEE802.11b standard is referred to as a direct sequence spread spectrum system.

In a direct sequence spread spectrum system, a signal containing information to be transmitted is directly spread by the transmitting end using a spreading code with a higher frequency than the signal to be transmitted. The receiving end despreads a received signal by the same spreading code as used in the transmitting end so as to extract information transmitted. A receiver in a direct sequence spread spectrum system is usually provided with a synchronization circuit for synchronizing the timing of the received signal with the timing of the transmitted signal, in addition to a demodulation circuit for demodulating the received signal. The synchronization circuit is capable of adjusting the timing of a signal by adjusting the amount of delay applied to the signal. For example, adjustment of the amount of delay applied to the signal is achieved by an FIR digital filter. An FIR digital filter comprises a plurality of taps connected in series. A signal output from each of the taps is multiplied by a coefficient (See reference (2) in the following Related Art List, for instance).

Related Art List

(1) Japanese Patent Application Laid-Open No. 2003-168999.
(2) Japanese Patent Application Laid-Open No. 2000-40942.

For the purpose of establishing synchronization between a received signal and a transmitted signal with high precision, an FIR digital filter generally processes the input signal at intervals shorter than the interval between signal samples (hereinafter, simply referred to as signals) constituting the transmitted signal. More specifically, oversampling at a rate higher than the original rate is applied on the received signal so that timing adjustment is applied on the oversampled signal. Alternatively, the input signal is upconverted to generate an oversampled signal so that timing adjustment is applied on the signal thus generated. These processes result in an increase in the number of taps constituting the FIR digital filter. An increase in the number of taps leads to an increase in the number of multipliers to be used for multiplication by coefficients, thereby bringing about an increase in the circuit scale. In apparatuses such as wireless LAN terminals, which are expected to be compact, it is desirable that the circuit scale be small.

### SUMMARY OF THE INVENTION

The present invention has been done in view of the aforementioned circumstances and its object is to provide a timing adjustment method which enables timing adjustment at a fast sampling rate and also prevents an increase in the circuit scale. Further, the invention relates to a digital filter and a receiver that uses the inventive method.

The present invention according to one aspect provides a digital filter. The digital filter according to this aspect comprises: an input unit which receives input sampled data at predetermined timings; a delay unit which sequentially delays the input data using a plurality of taps; a managing unit which manages a plurality of coefficients to be multiplied by a plurality of data items sequentially delayed by said plurality of taps; a multiplier unit which multiplies the plurality of data items sequentially delayed by the plurality of taps by the plurality of coefficients; and an adder which adds up multiplied data. The managing unit may retain, for each of the plurality of coefficients, a plurality of candidate coefficients corresponding to the plurality of timings of sampling, and switch between timings of sampling corresponding to added data produced by the adder, by switchably selecting one of the plurality of candidate coefficients retained.

In the filter described above, adjustment of timing of sampling of added data is not performed after increasing the sampling rate of the input data. Instead, timing adjustment is performed by retaining a plurality of types of coefficients to be multiplied by the input data and selecting one of the coefficients in accordance with required timing. This makes it possible to prevent an increase in the number of taps and an increase in the circuit scale, while enabling high-precision timing adjustment.

The sampling rate of the added data produced by the adder may be prescribed to be practically identical to the sampling rate of the input data received by the input unit, and the plurality of candidate coefficients retained by the managing unit may include a value corresponding to a predetermined timing and values corresponding to timings shifted with respect to the predetermined timing based on a tap interval. The digital filter may further comprise a shift unit which switches between combinations of the plurality of data items and the plurality of coefficients to be multiplied by each other in the multiplier unit. The digital filter according may further comprise: an accepting unit which accepts a timing of sampling required of the added data produced by the adder; and a control unit which directs the shift unit to switch the combination and directs the managing unit to switch selection, in accordance with the accepted timing. When a switch between combinations in the shift unit is necessary and the shift unit is not capable of the switch, the control unit may cause the adder unit to output data not necessary for a processor provided in a stage subsequent to the adder, by causing the managing unit to switch selection. The control unit may comprise a notification unit which notifies the processor of the output of the unnecessary data from the adder. When a switch between combinations in the shift unit is necessary and the shift unit is not capable of the switch, the control unit may skip at least one data item to be output from the adder to a processor provided in a stage subsequent to the adder, by causing the managing unit to switch selection. The control unit may comprise a notification unit which notifies the processor when at least one data item to be output from the adder is skipped.

In the arrangement for directing the shift unit and the managing unit to switch, an instruction is provided in some form to the shift unit and the managing unit. Practically, only one of the units may be given the instruction.

The phrase “practically identical” encompasses the case of being exactly identical but also encompasses a case of being displaced to a degree that does not affect the processor in a stage subsequent to the adder.

The data input to the input unit may comprise a plurality of data items constituting a group, and the control unit may direct the shift unit to switch between combinations and direct the managing unit to switch selection, at a timing corresponding to the end of the group. The sampling rate of the added data produced by the adder may be prescribed to be higher than the sampling rate of the input data input to the input unit, the managing unit may switch between plurality of coefficients retained while the plurality of data items sequentially delayed by the plurality of taps maintain constant values, the number of times of switching being commensurate with a ratio between the sampling rate of the added data produced by the adder and the sampling rate of the input data input to the input unit, the multiplier unit may execute multiplication on the plurality of data items maintaining constant values the same number of times commensurate with the ratio, and the managing unit may retain the plurality of candidate coefficients having values corresponding to a sampling rate equal to or greater than the least common multiple of the sampling rate of the added data produced by the adder and the sampling rate of the input data input to the input unit. The group may be prescribed for the input signal or may be a group for processing in the processor in the subsequent stage.

The present invention according to another aspect provides a receiver. The receiver according to this aspect comprises: an input unit which receives input sampled data at predetermined timings; a delay unit which sequentially delays the input data using a plurality of taps; a managing unit which manages a plurality of coefficients to be multiplied by a plurality of data items sequentially delayed by said plurality of taps; a multiplier unit which multiplies the plurality of data items sequentially delayed by the plurality of taps by the plurality of coefficients; an adder which adds up multiplied data; and a demodulation unit which demodulates added data. The managing unit may retain, for each of the plurality of coefficients, a plurality of candidate coefficients corresponding to a plurality of timings of sampling, and switch between timings of sampling corresponding to added data produced by the adder, by switchably selecting one the plurality of candidate coefficients retained.

The present invention according to still another aspect provides a timing adjustment method. The timing adjustment method according to this aspect comprises the steps of: multiplying a plurality of data items obtained by sequentially delaying data sampled at predetermined timings by a plurality of taps, by a plurality of coefficients; retaining, for each of the plurality of coefficients, a plurality of candidate coefficients corresponding to a plurality of timings of sampling; switchably selecting one of the plurality of candidate coefficients retained, and thereby switching between timings of sampling corresponding to added data produced by the adder.

Arbitrary combinations of the aforementioned constituting elements, and implementations of the invention in the form of methods, apparatuses, systems, recording mediums and computer programs may also be practiced as additional modes of the present invention.

Moreover, this summary of the invention does not necessarily describe all necessary features so that the invention may also be sub-combination of these described features.

### BRIEF DESCRIPTION OF THE DRAWINGS

FIG. 1 illustrates the burst format of a communications system according to an example of the present invention.

FIG. 2 illustrates the structure of a radio apparatus according to the example.

FIG. 3 illustrates the structure of a demodulation unit of FIG. 2.

FIG. 4 illustrates the structure of a first error detection unit of FIG. 3.

FIG. 5 illustrates the structure of an interpolation filter of FIG. 3.

FIGS. 6A-6B are diagrams illustrating the principle of detecting a timing error in a second error detection unit of FIG. 3.

FIG. 7 illustrates the structure of an FWT computation unit of FIG. 3.

FIG. 8 illustrates the structure of a first φ2 estimation unit of FIG. 7.

FIG. 9 illustrates the structure of a maximum value searching unit of FIG. 3.

FIG. 10 illustrates the constellation of signals subjected to Walsh transform to be selected by the maximum searching unit of FIG. 3.

FIGS. 11A-11D are diagrams illustrating the operating principle of the interpolation filter of FIG. 5.

FIG. 12 is a table listing coefficients retained in a coefficient retaining unit of FIG. 5.

FIG. 13 illustrates the interpolation operation by the interpolation filter of FIG. 5.

FIG. 14 illustrates the interpolation operation by the interpolation filter of FIG. 5.

FIGS. 15A-15E are charts illustrating the timing of operation of the interpolation filter of FIG. 5.

FIGS. 16A-16E are charts illustrating the timing of operation of the interpolation filter of FIG. 5.

FIGS. 17A-17E illustrate the operating principle of the interpolation filter according to a variation of the example.

FIG. 18 illustrates an alternative interpolation operation by the interpolation filter of FIG. 5.

FIG. 19 illustrates another alternative interpolation operation by the interpolation filter of FIG. 5.

### DETAILED DESCRIPTION OF THE INVENTION

The invention will now be described based on the following embodiments which do not intend to limit the scope of the present invention but exemplify the invention. All of the features and the combinations thereof described in the embodiments are not necessarily essential to the invention.

Before giving a specific description of the present invention, a summary of will be given. An example of the present invention relates to a wireless LAN apparatus, and particularly, to a receiver that complies with the IEEE 802.11b standard. The receiver subjects a received CCK modulated signal to fast Fourier transform (FWT) computation. The receiver further selects the largest correlation from a plurality of correlations obtained as a result of FWT computation and reconstructs a combination of phase signals corresponding to the largest correlation thus selected. Since a CCK modulated signal is generated based on differentially encoded signals, a receiver normally does not require correction of absolute phase.

The receiver according to the example corrects the absolute phase of the received CCK modulated signal before FWT computation. Further, the receiver derives approximate values from correlations generated by FWT computation such that an approximate correlation grows larger as it is removed from an in-phase axis and an orthogonal axis. As a result, the correlation to be finally selected will be assigned to a phase that provides a relatively large approximate value. This increases the likelihood of the relatively larger correlation being selected from a plurality of correlations, so that signal receiving performance is improved. The receiver according to the example is also provided with an interpolation filter for correcting a timing error between the transmitter and the receiver. A timing error between the transmitter and the receiver is detected in accordance with a predetermined method. The interpolation filter corrects the timing error thus detected. Generally, precision in correcting a timing error is improved by converting the received signal into a signal at a sampling rate faster than the original sampling rate. Timing error correction is then applied at a fast sampling rate. The process at a fast sampling rate, however, increases the number of taps in the interpolation filter, resulting in an increase in the circuit scale.

To address this, the inventive interpolation filter processes a received signal without converting the sampling rate of the received signal into a fast sampling rate. Meanwhile, to meet the requirement for high precision in timing correction, the interpolation filter retains a plurality of types of tap coefficients. One of the types is selected for use in accordance with the timing error detected. To put this more specifically, a set of plurality of tap coefficients corresponding to the respective taps corresponds, as a whole, to a given timing. Moreover, the interpolation filter retains a combination comprising a plurality of tap coefficients corresponding, for example, to a timing shifted by 1/4 samples with respect to a reference timing, a timing shifted by 1/2 samples with respect to the reference timing, etc.

If the detected timing error is “0”, the interpolation filter uses a plurality of tap coefficients corresponding to the reference timing. If the detected timing error is “1/4”, the interpolation filter uses a plurality of tap coefficients corresponding to the timing shifted by 1/4 samples with respect to the reference timing. According to this approach, the sampling rate of the signal processed by the interpolation filter is not raised to a fast rate. The invention only requires provision for retaining a plurality of types of tap coefficients and so does not bring about an increase in the number of taps and successfully prevents an increase in the circuit scale. By increasing the types of timings to which a plurality of tap coefficients correspond, the precision in timing correction is improved.

As an introduction to the first example of the invention, a brief description will be given of CCK modulation in the IEEE802.11b standard. In CCK modulation, 8 bits are grouped into one unit (hereinafter, this unit will be referred to as a CCK modulation unit). The 8 bits will be referred to as d1, d2, . . . d8 in the descending order of digits. The lower 6 bits in the CCK modulation unit are mapped onto the constellation diagram such that pairs [d3, d4], [d5, d6], [d7, d8] are mapped into the quadrature phase shift keying (QPSK) constellation points, respectively. The mapped phases will be denoted by (φ2, φ3, φ4), respectively. 8 spreading codes P1 through P8 are generated from the phases φ2, φ3, φ4, as given below.
P1=φ2+φ3+φ4
P2=φ3+φ4
P3=φ2+φ4
P4=φ4
P5=φ2+φ3
P6=φ3
P7=φ2
P8=0 (equation 1)

The higher two bits [d1, d2] of the CCK modulation unit are mapped into a constellation point of the differential encoding quadrature shift keying (DQPSK). The mapped phase will be denoted by φ1. φ1 corresponds to a spread signal. 8 chip signals X0 through X7 are generated from the spread signal φ1 and the spreading codes P1 through P8, as given below.
X0=e^{j(φ1+P1})
X1=e^{j(φ1+P2})
X2=e^{j(φ1+P3})
X3=−e^{j(φ1+P4})
X4=e^{j(φ1+P5})
X5=e^{j(φ1+P6})
X6=−e^{j(φ1+P7})
X7=e^{j(φ1+P8}) (equation 2)

A transmitter transmits the chip signals X0 through X7 in the stated order (hereinafter, a time sequence unit comprising the chip signals X0 through X7 will also be referred to as a CCK modulation unit). In the IEEE802.11b standard, in addition to using CCK modulation, DBPSK and DQPSK phase modulated signals are spread by known spreading codes and transmitted.

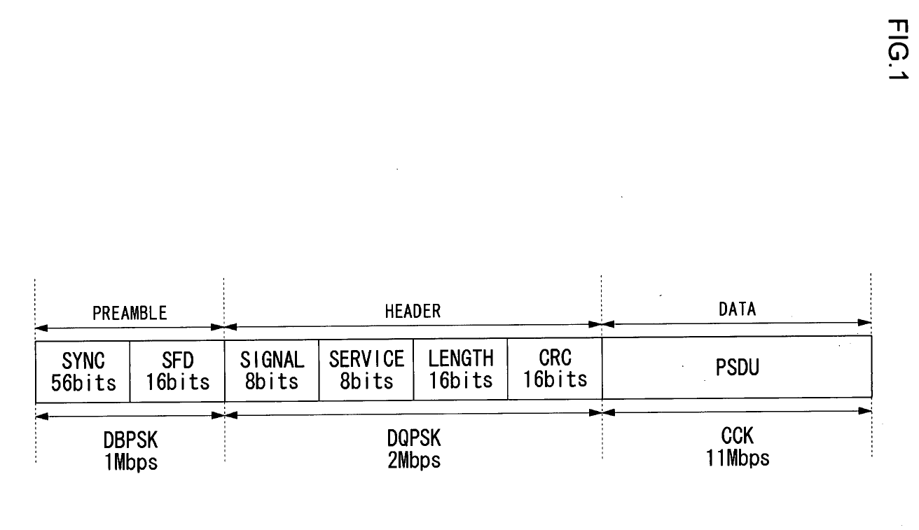

FIG. 1 shows a burst format in a communications system according to the first example of the present invention. The burst format corresponds to short PLCP of the IEEE802.11b standard. As illustrated, the burst signal includes preamble, header and data fields. The preamble is transmitted at a transmission rate of 1 Mbps according to the DBPSK modulation scheme. The header is transmitted at a transmission rate of 2 Mbps according to the DQPSK modulation scheme. The data is transmitted at a transmission rate of 11 Mbps according to the CCK modulation scheme. The preamble includes SYNC of 56 bits and SFD of 16 bits. The header includes SIGNAL of 8 bits, SERVICE of 8 bits, LENGTH of 16 bits and CRC of 16 bits. The length of PSDU corresponding to the data is variable.

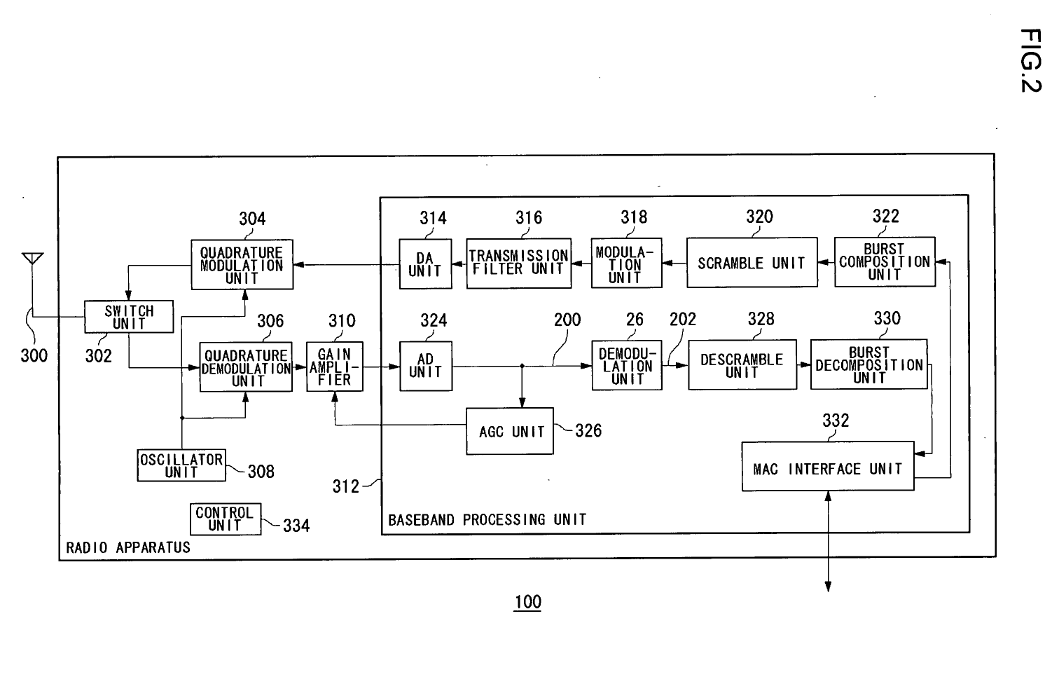

FIG. 2 shows the structure of a radio apparatus 100 according to the example. The radio apparatus 100 includes an antenna 300, a switch unit 302, a quadrature modulation unit 304, a quadrature demodulation unit 306, an oscillation unit 308, a gain amplifier 310, a baseband processing unit 312 and a control unit 334. The baseband processing unit 312 includes a DA unit 314, a transmission filter unit 316, a modulation unit 318, a scramble unit 320, a burst composition unit 322, an AD unit 324, an AGC unit 326, a demodulation unit 26, a descramble unit 328, a burst decomposition unit 330 and a MAC interface unit 332. The signals involved include a digital received signal 200 and an output signal 202.

The antenna 300 transmits and receives a radio frequency signal. The switch unit 302 outputs an signal input from the quadrature modulation signal 304 to the antenna 300 or outputs a signal input from the antenna 300 to the quadrature demodulation unit 306. Since the signal input from the quadrature modulation unit 304 and the signal output to the quadrature demodulation unit 306 are intermediate frequency signals. The switch 302 converts the signal input from the quadrature modulation unit 304 into a radio frequency signal before outputting the same to the antenna 300, and also converts the signal input from the antenna 300 into an intermediate frequency signal before outputting the same to the quadrature demodulation unit 306. The oscillation unit 308 generates a signal of a predetermined frequency. In this example, the oscillator generates a sinusoidal wave. The quadrature demodulation unit 306 subjects the signal input from the switch unit 302 to quadrature detection, based on the signal of the predetermined frequency input from the oscillation unit 308. Generally, the base band signal subjected to quadrature detection should be illustrated by two signal lines to show its in-phase component and quadrature component. FIG. 2, however, illustrates the components as being combined. The same convention will be observed throughout the drawings.

The gain amplifier 310 amplifies the signal subjected to quadrature detection in the quadrature demodulation unit 306 by a gain set by the AGC unit 326. The AGC unit controls the gain so that the amplitude of the signal amplified by the gain amplifier 310 fits in the dynamic range of the AD unit 324. The AD unit 324 subjects the signal amplified by the gain amplifier 310 to AD conversion so as to output a digital received signal 200. Since the receiver is intended to be used in a wireless LAN system that complies with the IEEE802.11b standard, the maximum signal transmission rate is llMbps, as indicated in FIG. 1. The AD unit 324 oversamples a signal at a sampling rate twice as fast as the transmission rate. Therefore, the sampling rate of the digital received signal 200 is 22 MHz. The demodulation unit 26 demodulates the digital received signal 200 so as to output the output signal 202. The digital received signal 200 is a spread spectrum signal and the digital received signal 202 is an information bit series. The descramble unit 328 descrambles the output signal 202. The burst decomposition unit 330 decomposes a burst into individual components and outputs the components to the MAC interface unit 332. The MAC interface unit 332 receives a bit series to be transmitted from an external source.

The burst composition unit 322 constructs a burst signal from input bit series. The scramble unit 320 scrambles the burst signal. The modulation unit 318 modulates the signal input from the scramble unit 320 and outputs the scrambled signal to the transmission filter unit 316. Modulation here encompasses spectrum spreading. The transmission filter unit 316 cuts off high-frequency components included in the modulated signal. The DA converter unit 314 subjects the signal input from the transmission filter unit 316 to DA conversion. The quadrature modulation unit 304 subjects the signal input from the DA unit 314 to quadrature modulation and outputs the resultant intermediate frequency signal to the switch unit 302. The control unit 28 controls the timing in the radio apparatus 100.

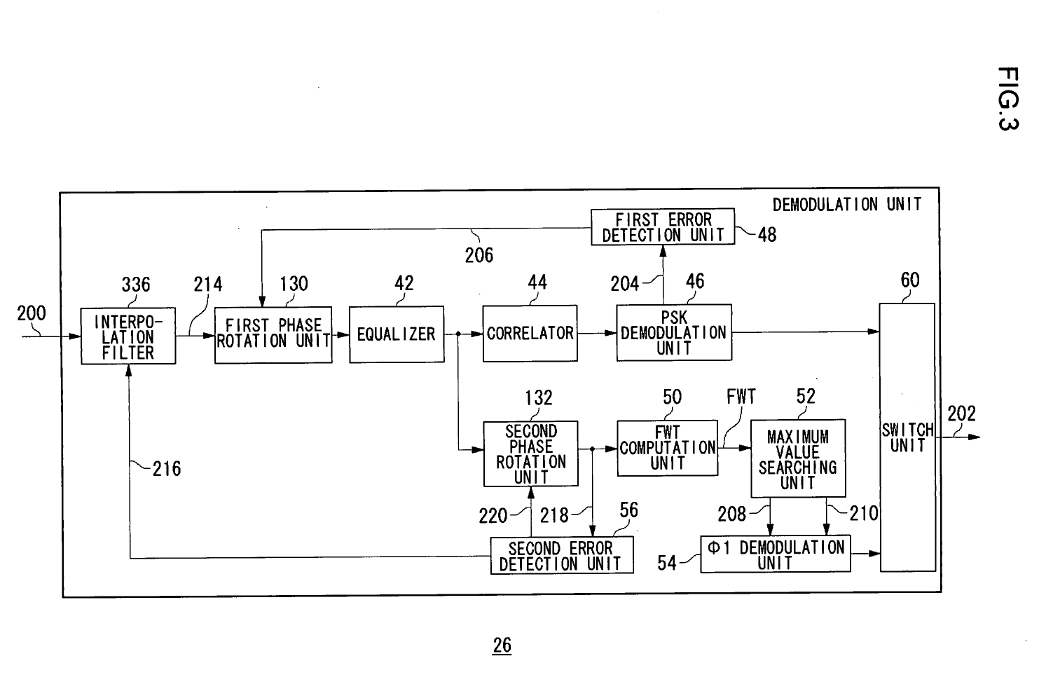

The structure as described above may be implemented by hardware including a CPU, a memory and an LSI and by software including a program provided with reservation and management functions loaded into the memory. FIG. 3 depicts function blocks implemented by cooperation of the hardware and software. Therefore, it will be obvious to those skilled in the art that the function blocks may be implemented by a variety of manners including hardware only, software only or a combination of both.

FIG. 3 illustrates the structure of the demodulation unit 26. The modulation unit 26 comprises an interpolation filter 336, a first phase rotation unit 130, an equalizer 42, a correlator 44, a PSK demodulation unit 46, a first error detection unit 48, a second phase rotation unit 132, an FWT computation unit 50, a maximum value searching unit 52, a φ1 demodulation unit 54, a second error detection unit 56 and a switch unit 60. The signals involved include a demodulated signal 204, a phase error signal 206, a filter output signal 214, a timing control signal 216, a phase correction signal 220, a rotated signal 218, a φ1 signal 208, a φ component signal 210 and a Walsh transform value FWT.

The interpolation filter 336 corrects a timing error of the digital received signal 200 in accordance with the timing control signal 216 output from the second error detection unit 56. The interpolation filter 336 outputs the corrected signal as the filter output signal 214. The structure of the interpolation filter 326 will be described later. The digital received signal 200 is a CCK modulated signal generated from a plurality of phase signals at the transmitting end (not shown) in an interval for data in the burst format of FIG. 1. A CCK modulation unit comprising a plurality of chips represents a symbol.

The first phase rotation unit 130 rotates the phase of the filter output signal 214 in accordance with the phase error signal input from the first error detection unit 48 described later. As a result of the rotation, phase rotation not derived from CCK modulation is cancelled. The rotation by the first phase rotation unit 130 may be effected by vector computation on complex components or addition and subtraction of phase components.

The equalizer 42 eliminates effects from multipath transmission included in the signal output from the first phase rotation unit 130. The equalizer 42 is composed of filters of a transversal type. A decision feedback equalizer (DFE) may be added to the filters of a transversal type. The equalizer 42 may output the input signal intact until tap coefficients of the equalizer 42 are set.

The correlator 44 subjects the signal output from the equalizer 42 to a correlating process using predetermined spreading codes, so as to despread the phase modulated signals, such as the preamble and the header of the bust format of FIG. 1, spread by the same predetermined spreading codes. The correlation may be a process of a sliding type or a process of a matched filter type.

The PSK demodulation unit 46 demodulates the despread signal despread by the correlator 44. The modulation scheme of the despread signal is DBPSK or DQPSK so that demodulation is performed using differential detection. The first phase error detection unit 48 detects a phase error in accordance with the demodulated signal 204. The detected phase error is output as the phase error signal 206. Details will be described later.

The second phase rotation unit 132 is provided with the function of rotating a signal phase. The second phase rotation unit 132 adjusts the amount of rotation in accordance with the phase error signal 220 indicating the phase error detected by the second error detection unit 56 and rotates the signal equalized by the equalizer 42 by the adjusted amount of rotation. It is ensured that, as a result of rotation, the rotated signal approaches one of the phases to which the CCK modulated signals are assigned. While the first phase rotation unit 130 performs a similar process, the second phase rotation unit 132 corrects a residual component of phase error that remains after the process by the first phase rotation unit 130. The second phase rotation unit 132 outputs the rotated signal as the rotated signal 218.

The second phase error detection unit 56 detects the phase error and the timing error by referring to rotated signal 218 from the second phase rotation unit 132. A method of detection will be described later. The second error detection unit 56 outputs the phase error and the timing error detected as the phase correction signal 220 and the timing control signal 216.

Referring back to FIG. 3, the FWT computation unit 50 subjects to FWT computation a value which corresponds to the CCK modulated signal such as the data segment of the burst format of FIG. 1 and which results from conversion in the decision unit 150. The FWT computation unit 50 outputs a resultant Walsh transform value FWT. As described before, the rotated signal 218 is a signal corrected for phase error and timing error. To describe the process in the FWT computation unit 50 in further detail, it receives the chip signals, CCK modulation units, and outputs correlations, 64 Walsh transform values FWT, by examining correlation between the chip signals.

The maximum value searching unit 52 receives the 64 Walsh transform values FWT and selects a single Walsh transform value FWT, by referring to the magnitude of the values. In accordance with the selected Walsh transform value FWT, the maximum value searching unit 52 outputs the φ1 signal 208 and the φ component signal 210, the φ1 signal corresponding to the signal prior to φ1 differential detection and the φ component signal being a combination of φ2 through φ4. The φ1 demodulation unit 54 subjects the φ1 signal 208 to differential detection so as to generate φ1. The φ1 demodulation unit 54 further reconstructs information bits d1, d2 . . . d8 that are target for transmission from the combination of φ1 through φ4. The FWT computation unit 50, the maximum value searching unit 52, the φ1 demodulation unit 54 demodulates the signal corrected for the phase error and the timing error by the interpolation unit 336, the first phase rotation unit 130 and the second phase rotation unit 56.

The switch unit 60 selects either the signal output from the PSK demodulation unit 46 or the signal output from the φ1 demodulation unit 54. The switch unit 60 outputs the selected signal as the output signal 202. In an interval including the preamble and the header of the burst format of FIG. 1, the switch unit 60 selects the signal output from the PSK demodulation unit 46 and the selects the signal output from the φ1 demodulation unit 54 in an interval including the data of the burst format. The switch unit 60 outputs an inverse of the selected signal.

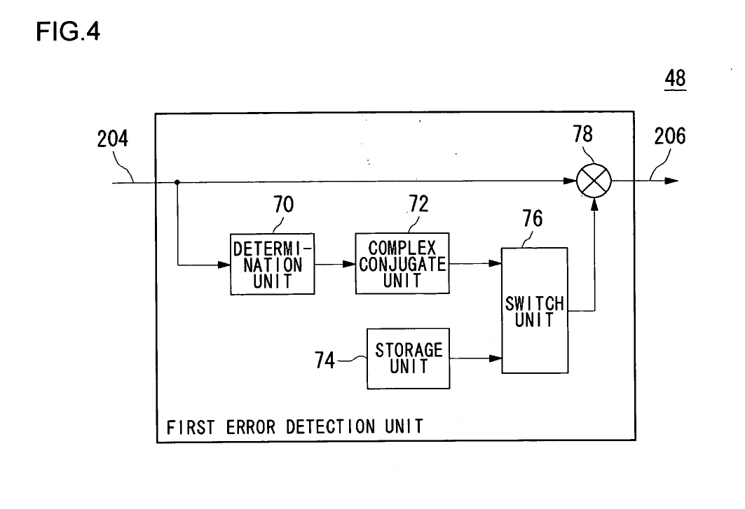

FIG. 4 shows a construction of the first error detection unit 48. The first error detection unit 48 includes a storage unit 74, a determination unit 70, a complex conjugate unit 72, a switch unit 76 and a multiplier unit 78.

The storage unit 74 stores a known signal corresponding to the preamble field of the burst format of FIG. 1 and outputs the known signal at a point of time corresponding to the preamble field.

The determination unit 70 determines the value of the despread signal 204 in a time interval for the header field of the burst format of FIG. 1, in accordance with a predetermined threshold value for determination. The determination is made both for the in-phase component and the quadrature component of the despread signal 204. In the interval for the data field of the burst format of FIG. 1, the phase error signal 206, determined in the interval for the header field, may continue to be output.

The complex conjugate unit 72 calculates a complex conjugate of the signal subject to determination by the determination unit 70. The switch unit 76 outputs a signal from the storage unit 74 in a time interval for the preamble and outputs a signal from the complex conjugate unit 72 in a time interval for the header field.

The multiplier unit 78 multiplies a reference signal output from the switch unit 76 with the despread signal 204 so as to output an error of the despread signal 204 with respect to the reference signal as the phase error signal 206.

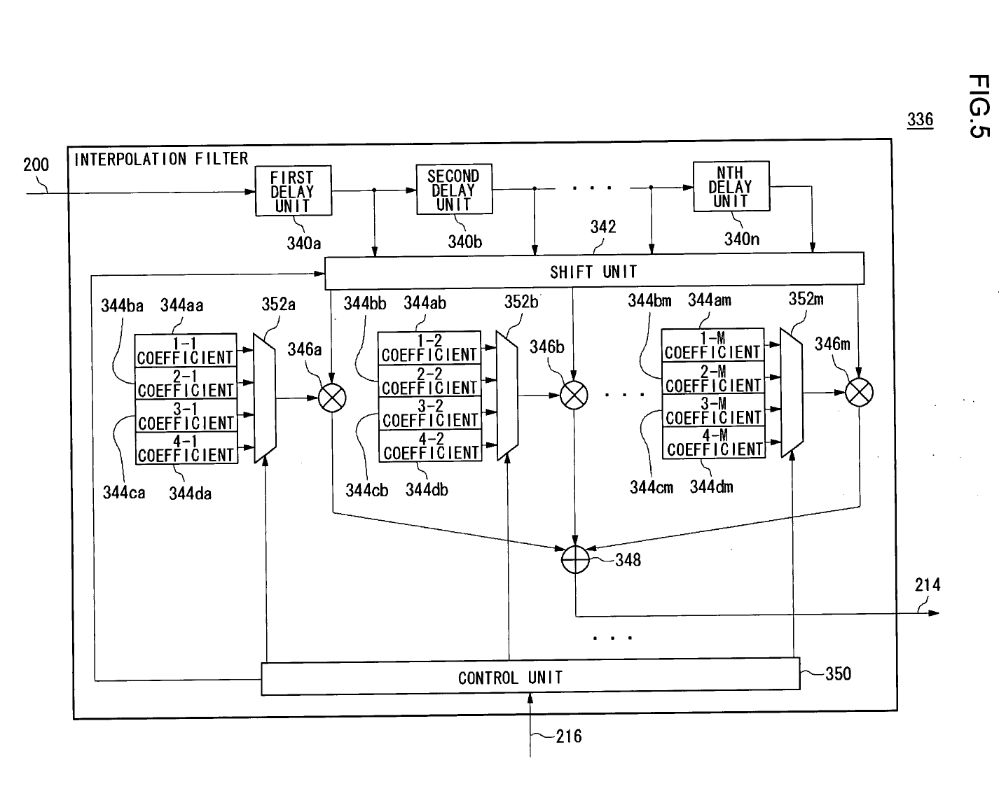

FIG. 5 illustrates the structure of the interpolation filter 336. The interpolation filter 336 includes: a first delay unit 340a, a second delay unit 340b and an Nth delay unit 340n, generically referred to as delay units 340; a shift unit 342, 1-1 coefficient retaining unit 344aa, 1-2 coefficient retaining unit 344ab and 1-M coefficient retaining unit 344am, 2-1 coefficient retaining unit 344ba, 2-2 coefficient retaining unit 344bb, 2-M coefficient retaining unit 344bm, 3-1 coefficient retaining unit 344ca, 3-2 coefficient retaining unit 344cb, 3-M coefficient retaining unit 344 cm, 4-1 coefficient retaining unit 344da, 4-2 coefficient retaining unit 344db, 4-M coefficient retaining unit 344dm, generically referred to as coefficient retaining units 344; a first multiplier unit 346a, a second multiplier unit 346b and an Mth multiplier unit 346m, generically referred to as multiplier units 346; an adder unit 348; a control unit 350; a first selector unit 352a, a second selector unit 352b and an Mth selector unit 352m, generically referred to as selector units 352.

As described before, the digital received signal 200 is derived from sampling in the AD unit 324 (not shown in FIG. 5). The delay units 340 comprise a plurality of taps for delaying individual samples in the input digital received signal 200 sequentially (hereinafter, such a sample will simply be referred to as the digital received signal 200). Each one of the delay unit 340 delays the digital received signal 200 by a time commensurate with the sampling rate and, more specifically, by an inverse of the sampling rate of 22 MHz.

The shift unit 342 changes combinations of the plurality of digital received signals 200 delayed by the delay units 340 with the multipliers 346. More specifically, the shift unit 342 connects the digital received signal 200 output from the first delay unit 340a to one of the plurality of multipliers 346 including the first multiplier unit 346a and the second multiplier unit 346b, in accordance with a direction from the control unit 350 described later. When, for example, the digital received signal 200 output from the first delay unit 340a is connected to the first multiplier unit 346a, the digital received signal 200 output from the second delay unit 340b is connected to the second multiplier unit 346b, and so on, so that connections are sequentially established. The number of delay units 340 and the number of multiplier units 346 are generically represented as N and M, respectively, where M could be larger than N. It will be assumed that M is larger than N. By allowing the shift unit 342 to switchably deliver the plurality of digital signals 200 delayed by the delay units 340 to the multiplier units 346, each of the digital received signals 200 is switchably multiplied by different coefficients.

The coefficient retaining unit 344 manages a plurality of coefficients to be multiplied by the plurality of digital received signals 200 delayed by the delay unit 340. By selecting one of the coefficients for multiplication by each of the plurality of digital received signals 200 delayed by the delay units 340, the coefficients stored in the coefficient retaining unit 344 may be viewed as candidates for coefficients. In the following description, the phrases “candidate coefficients” and “coefficients” will be used without making any distinction between them. The coefficient retaining unit 344 retains a plurality of coefficients corresponding to a plurality of timings of sampling. The “plurality of timings of sampling” include a predetermined timing and timings shifted in time from the predetermined timing by an amount that is based on a tap interval. More specifically, a plurality of coefficients stored in 1-1 coefficient retaining unit 344aa, 1-2 coefficient retaining unit 344ab and 1-M coefficient retaining unit 344am are coefficients corresponding to the reference timing of 0 timing shift amount. These coefficients as a whole will be referred to as “0/8-chip shift series” and are individually identified as the “first coefficient”, the “second coefficient” and the “Mth coefficient” in the series.

The plurality of coefficients stored in 2-1 coefficient retaining unit 344ba, 2-2 coefficient retaining unit 344bb and 2-M coefficient retaining unit 344bm correspond to the timing of a shift amount of 1/8 chips. These coefficients as a whole will be referred to as “1/8-chip shift series” and are individually identified as the “first coefficient”, the “second coefficient” and the “Mth coefficient” in the series. The plurality of coefficients stored in 3-1 coefficient retaining unit 344ca, 3-2 coefficient retaining unit 344cb and 3-M coefficient retaining unit 344 cm correspond to the timing of a shift amount of 2/8 chips. These coefficients as a whole will be referred to as “2/8-chip shift series” and are individually identified as the “first coefficient”, the “second coefficient” and the “Mth coefficient” in the series. The plurality of coefficients stored in 4-1 coefficient retaining unit 344da, 4-2 coefficient retaining unit 344db and 4-M coefficient retaining unit 344dm correspond to the timing of a shift amount of 3/8 chips. These coefficients as a whole will be referred to as “3/8-chip shift series” and are individually identified as the “first coefficient”, the “second coefficient” and the “Mth coefficient” in the series.

The selector unit 352 selects one of the coefficients retained in the coefficient retaining unit 344, i.e., one of the “1/8-chip shift series”, the “2/8-chip shift series” and the “3/8-chip shift series”, in accordance with an instruction from the control unit 350. The selected coefficient is output to the multiplier unit 346. By switching between coefficients retained in the coefficient retaining unit 344, the sampling timing corresponding to the filter output signal 214 ultimately output is switched. Details of this will be described later.

The multiplier unit 346 multiplies the plurality of digital received signals 200 delayed by the delay units 340 by the coefficients selected by the selector unit 352. Since the digital received signal 200 and the coefficient subject to the multiplication in the multiplier unit 346 are both complex numbers each having an in-phase component and a quadrature component, the multiplication in the multiplier unit 346 is a complex multiplication. The adder unit 348 calculates a sum of the results of multiplication by the multiplier unit 346 and outputs the sum as the filter output signal 214. The sampling rate of the filter output signal 214 is prescribed to be identical to the sampling rate of the digital received signal 200.

The control unit 350 receives an instruction relative to the timing of sampling required of the filter output signal 214 as the timing control 216. The instruction included in the timing control signal 216 relative to the timing dictates, for example, that the timing should be advanced by 1/8 chips. In accordance with the instruction, the control unit 350 directs the shift unit 342 to switch from one combination to another and directs the selector unit 352 to switch between coefficients retained in the coefficient retaining unit 344. Alternatively, the control unit 350 may give a direction to only one of the shift unit 342 and the selector unit 352, in accordance with the timing of sampling required.

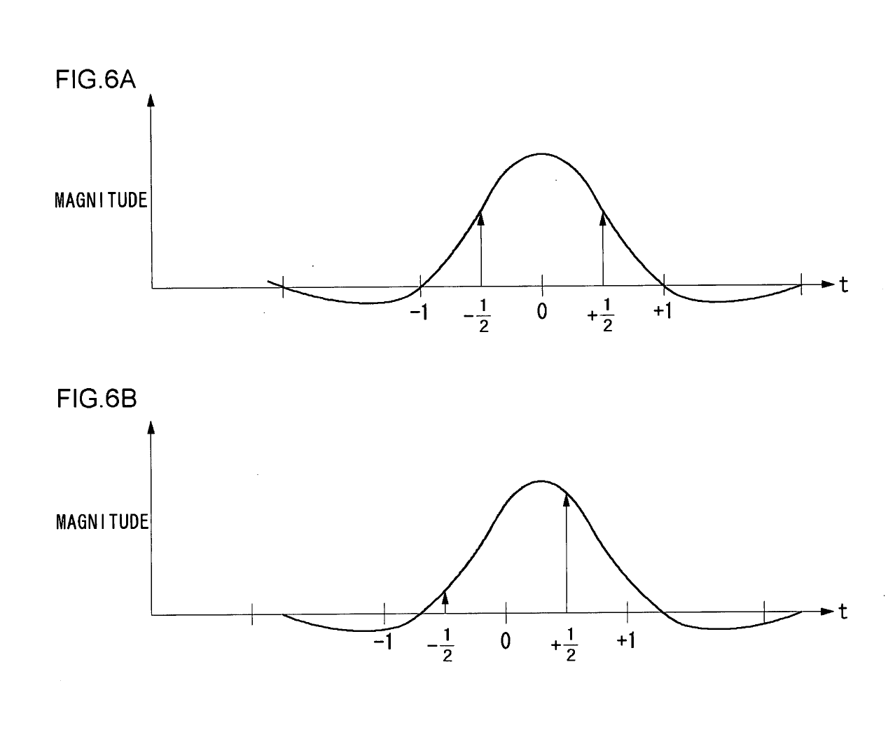

FIGS. 6A-6B are diagrams illustrating the principle of detecting a timing error in the second error detection unit 56. FIG. 6A is a graph illustrating the waveform occurring when the timing error is 0, i.e., when the radio apparatus 100 and the apparatus (not shown) with which it is communicating are practically completely synchronized in operation. The illustrated waveform is that of one sampled data constituting the rotated signal 218 and occurring at a given timing. As illustrated, the Nyquist criterion is fulfilled. Accordingly, the magnitude of the waveform is 0 at the timings “+1” and “−1” for the adjacent chips. The magnitude at “+1/2” and that of “−1/2”, at the center of chip interval, are identical. At timing “0”, the magnitude is at a peak.

FIG. 6B is a graph illustrating the waveform occurring when the radio apparatus 100 and the apparatus (not shown) with which it is communication are not synchronized. The illustrated waveform is that of one sampled data constituting the rotated signal 218 and occurring at a given timing. As illustrated, the magnitude of the waveform is not 0 at the timings “+1” and “−1” for the adjacent chips. The magnitude at “+1/2” and that of “−1/2”, at the center of chip interval, are not identical. The peak occurs at a timing outside the timing “0”. The second error detection unit 56 is capable of detecting the timing error in sampling introduced in the rotated signal 218, by, for example, detecting a difference between the magnitude at “+1/2” and that of “−1/2”. For detection of the phase error in addition to the timing error, the second error detection unit 56 may have the structure similar to that of the first error detection unit 48 illustrated in FIG. 4.

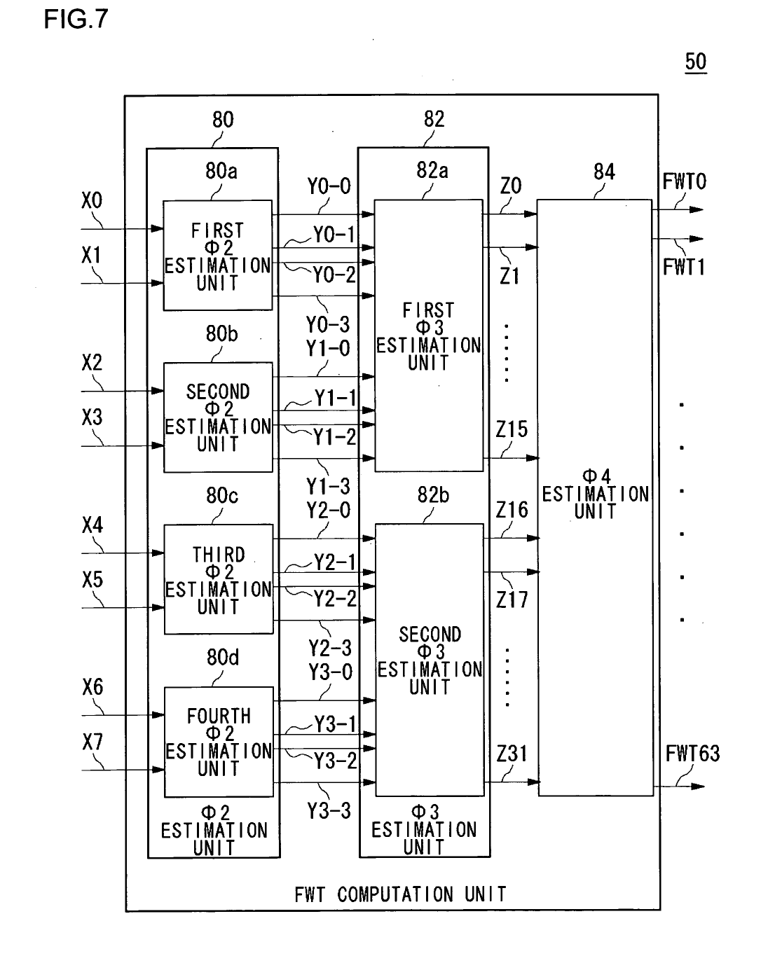

FIG. 7 shows the structure of the FWT computation unit 50. The FWT computation unit 50 includes a first φ2 estimation unit 80a, a second φ2 estimation unit 80b, a third φ2 estimation unit 80c and a fourth φ2 estimation unit 80d, generically referred to as a φ2 estimation unit 80, and a first φ3 estimation unit 82a and a second φ3 estimation unit 82b, generically referred to as a φ3 estimation unit 82, and a φ4 estimation unit 84. The signals involved include X0, X1, X2, X3, X4, X5, X6 and X7, generically referred to as chip signals X, Y0-0, Y0-1, Y0-2, Y0-3, Y1-0, Y1-1, Y1-2, Y1-3, Y2-0, Y2-1, Y2-2, Y2-3, Y3-0, Y3-1, Y3-2, Y3-3, generically referred to as first correlations Y, and Z0, Z1, Z15, Z16, Z17 and Z31, generically referred to as second correlations Z, and FWT0, FWT1 and FWT63, generically referred to as Walsh transform values FWT. The chip signals X correspond to the rotated signal 218 described above.

The φ2 estimation unit 80 each receive two chip signals X. For example, a unit receives X0 and X1, rotate the phase of X0 by π/2, π and 3π/2, add X1 and X0 thus rotated so as to output Y0-1 through Y0-3, respectively. When the phase of X0 thus rotated equals the phase φ2, a first correlation Y resulting from the addition is corresponding large. This is how φ2 is estimated.

The φ3 estimation unit 82 operates similarly as the φ2 estimation unit 80. For example, the φ3 estimation unit 82 receives Y0-0 through Y0-3 and Y1-0 through Y1-3 so as to output Z0 through Z15. φ3 is estimated by referring to the magnitude of a second correlation Z. The φ4 estimation unit 84 operates similarly to the φ2 estimation unit 80. The φ4 estimation unit 84 receives Z0 through Z31 so as to output FWT0 through FWT 63. φ4 and φ1 are estimated by referring to the magnitude of the Walsh transform value FWT.

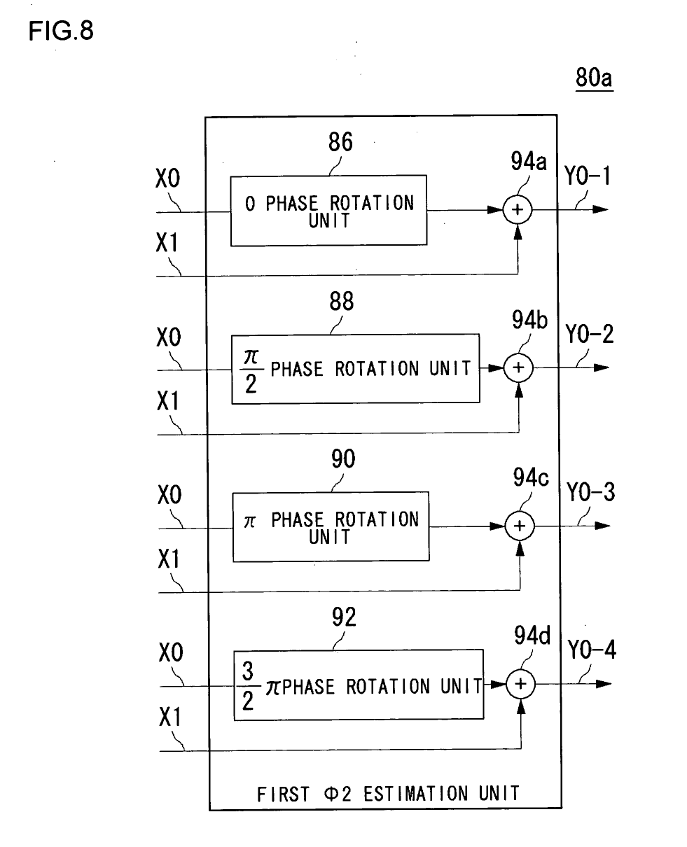

FIG. 8 shows the structure of the first φ2 estimation unit 80a. The first φ2 estimation unit 80a includes a 0 phase rotation unit 86, a π/2 phase rotation unit 88, a π phase rotation unit 90, a 3/2π phase rotation unit 92, a first addition unit 94a, a second addition unit 94b, a third addition unit 94c and a fourth addition unit 94d, generically referred to as an addition unit 94. The 0 phase rotation unit 86, the π/2 phase rotation unit 88, the π phase rotation unit 90, the 3/2π phase rotation unit 92 rotate the phase of X0 by 0, π/2, π, 3π/2, respectively. The outputs are added to X1 in the addition unit 94.

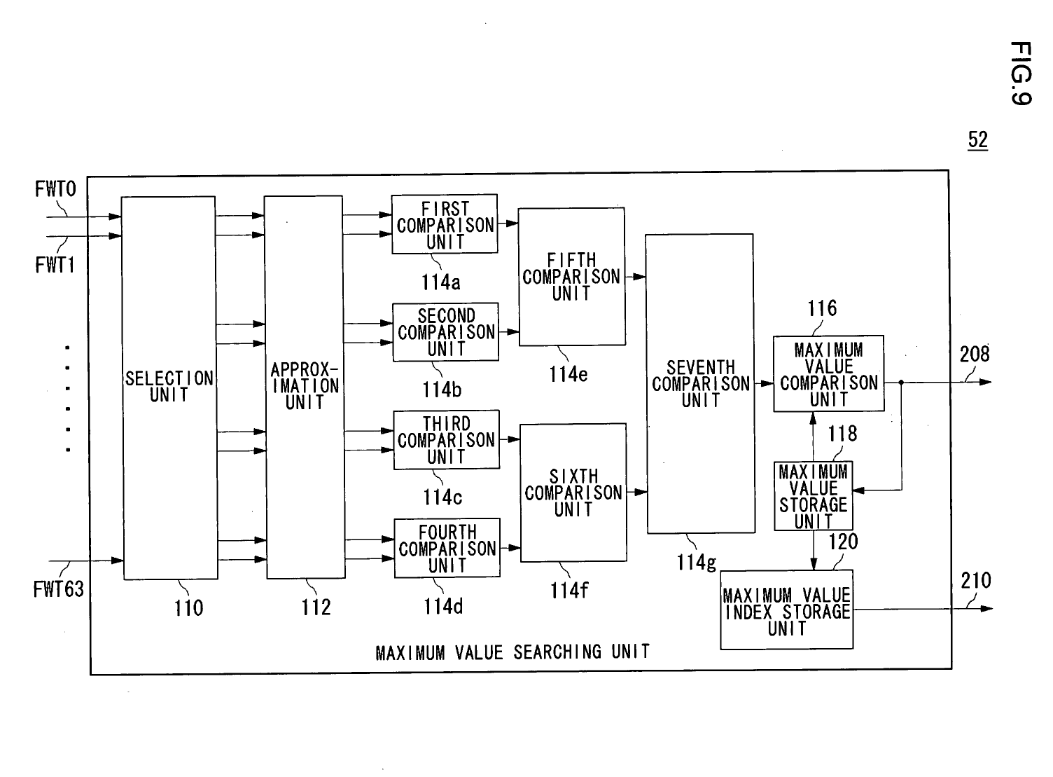

FIG. 9 shows the structure of the maximum value searching unit 52. The maximum value searching unit 52 includes a selection unit 110, an approximation unit 112, a first comparison unit 114a, a second comparison unit 114b, a third comparison unit 114c, a fourth comparison unit 114d, a fifth comparison unit 114e a sixth comparison unit 114f, a seventh comparison unit 114g, generically referred to as a comparison unit 114, a maximum value comparison unit 116, a maximum value storage unit 118 and a maximum value Index storage unit 120.

The selection unit 110 receives 64 data items FWT0 through FWT63 and outputs the data in units of 8 items. For example, the selection unit 110 outputs FWT0 through FWT7 initially and subsequently outputs FWT8 through FWT15.

The approximation unit 112 determines the magnitude of Walsh transform value FWT by approximation. Assuming that the in-phase component and the quadrature component of a Walsh transform FWT are denoted by I and Q, the magnitude R is given by a sum of absolute values.
R=|I|+|Q| (equation 3)

The comparison unit 114 compares R for eight data items with each other and selects the largest Walsh transform value FWT.

The maximum value comparison unit 116 compares a selected one of FWT0 through FWT63 with the maximum value determined from a previous search in the 8 Walsh transform values FWT, so as to select the larger of the compared values. Finally, the maximum value comparison unit 116 selects the largest Walsh transform value FWT from FWT0 through FWT63. The selected Walsh transform value FWT is stored in the maximum value storage unit 118. The maximum value Index storage unit 120 outputs a combination of φ2 through φ4 corresponding to the maximum Walsh transform value FWT ultimately stored in the maximum value storage unit 118.

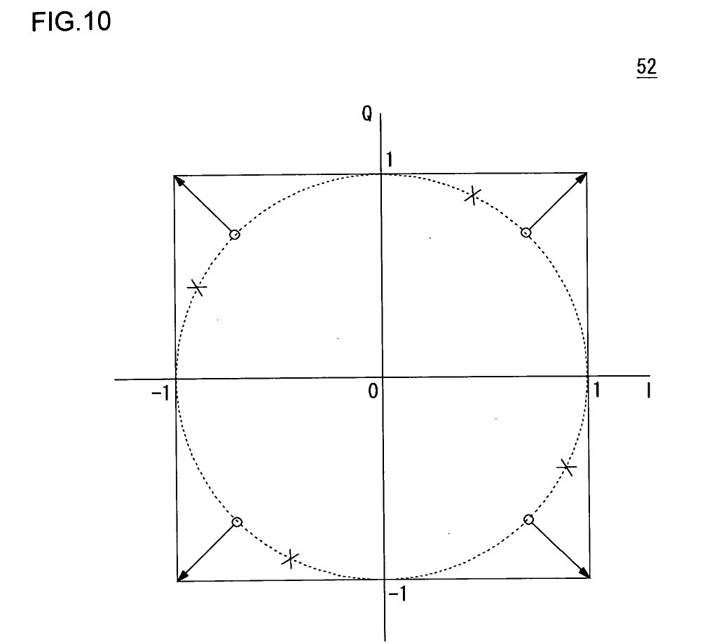

FIG. 10 shows a constellation of the signals subjected to Walsh transform to be selected by the maximum value searching unit 52. The I-axis and the Q-axis in the figure represent an in-phase axis and an quadrature axis, respectively. Encircled points indicated in the figure represent a constellation of ideal Walsh transform values FWT in a case where there is no phase error. A dotted line indicates a plot of equal magnitudes of Walsh transform values FWT determined as a normal square sum. The square in the figure indicates the equal magnitudes of the Walsh transform values FWT determined as an absolute sum and corresponding to the dotted line. The values “1” and “−1” shown on the I-axis and the Q-axis are normalized Walsh transform values FWT. Actual Walsh transform values FWT may be different.

A displacement between the square and the dotted line indicates an error occurring as a result of approximation. The error is large at π/4, 3π/4, 5π/4 and 7π/4. Since the approximated value is larger than the non-approximated value at phases at which the constellation points of the Walsh transform values FWT should be assigned, as illustrated, the likelihood of the Walsh transform values FWT assigned to those phases being selected is increased so that the receiving performance is improved. When a phase error and a timing error occur, the constellation points of the Walsh transform values FWT are indicated by × in the figure. Therefore, the likelihood of those Walsh transform values FWT being selected is decreased so that there is a possibility that the receiving performance is degraded. To prevent this, the interpolation filter 336, the first phase rotation unit 130, the second phase rotation unit 132 and the second error detection unit 56 are used in this example to correct the timing error.

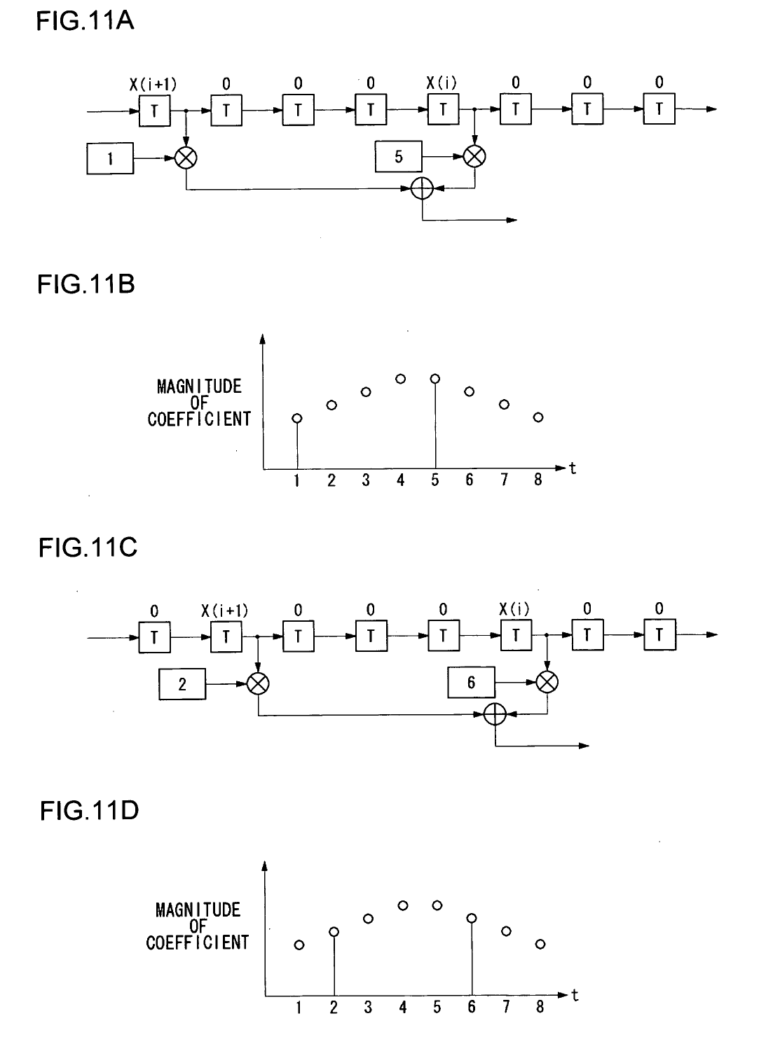

FIGS. 11A-11D illustrate the operating principle of the interpolation filter 336. FIG. 11A illustrates the process performed by a conventional interpolation filter, instead of the inventive filter, for conversion into a fast sampling rate. The operating principle of the interpolation filter 336 according to our example will be explained by explaining the operating principle of a conventional interpolation filter. Taps denoted by “T” in the illustration correspond to the delay units 340. The delay time applied in the delay units 340 is an inverse of the sampling time in the AD unit 324, whereas the delay time applied in “T” is an inverse of the sampling rate that is four times as fast as the sampling rate of the AD unit 324. Sampled obtained by sampling in the AD unit 324 are indicated by X(i) and X(i+1) in the illustration. Samples inserted for conversion into the sampling rate four times as fast are indicated by “0”. As illustrate, the sampling rate is changed by inserting “0”s with a zero magnitude. Multiplication of sample “0” by any number invariably results in “0” so that only those results of multiplication by X(i) and X(i+1) will be effective. Coefficients to be multiplied by samples including X(i) and X(i+1) are indicated as “1”, “2”, . . . , from the left of the diagram. Thus, coefficients identified by “1” and “5” are multiplied by X(i) and X(i+1). The results of multiplication are added to each other before being output.

FIG. 11B illustrates the magnitude of coefficients of FIG. 11A. The magnitude of each of the coefficients, identified as “1”, “2”, . . . from the left as mentioned above, is plotted in the graph. The magnitude of coefficient increases between the coefficients “1” and “4”, and decreases between the coefficients “5” and “8”. The coefficients “1” and “5” are used in multiplication in accordance with the structure of FIG. 11A. In a similar way to FIG. 11A, Fig. 11C illustrates the process performed by a conventional interpolation filter for conversion into a fast sampling rate. The structure is the same as that of FIG. 11A, a difference being that X(i) and X(i+1) occur in taps “T” shifted rightward by one tap, with respect to the configuration of FIG. 11A. Consequently, only the coefficients “2” and “6” corresponding to X(i) and X(i+1) are conductive to effective multiplication. FIG. 11D illustrates the magnitude of coefficients of FIG. 11C. The magnitude of each of the coefficients “1” through “8” is identical to the corresponding magnitude of FIG. 11B. The coefficients “2” and “6” are used in multiplication in accordance with the structure of FIG. 1C.

Referring to FIG. 11A-11D, multiplication by samples “0” only produces results that can be neglected in the type of multiplication as illustrated in FIGS. 11A and 11C for increasing the input signal sampling rate four times. This only requires a change in coefficients to be multiplied by the input samples X(i) and X(i+1), while the input samples themselves remain unchanged. It will be understood that, by changing the coefficients to be multiplied by the input signal (sample) in adaptation to the required timing, and not requiring a change in the sampling rate of the input signal, the timing of the input signal can be changed. This is the operating principle of the inventive interpolation filter 336.

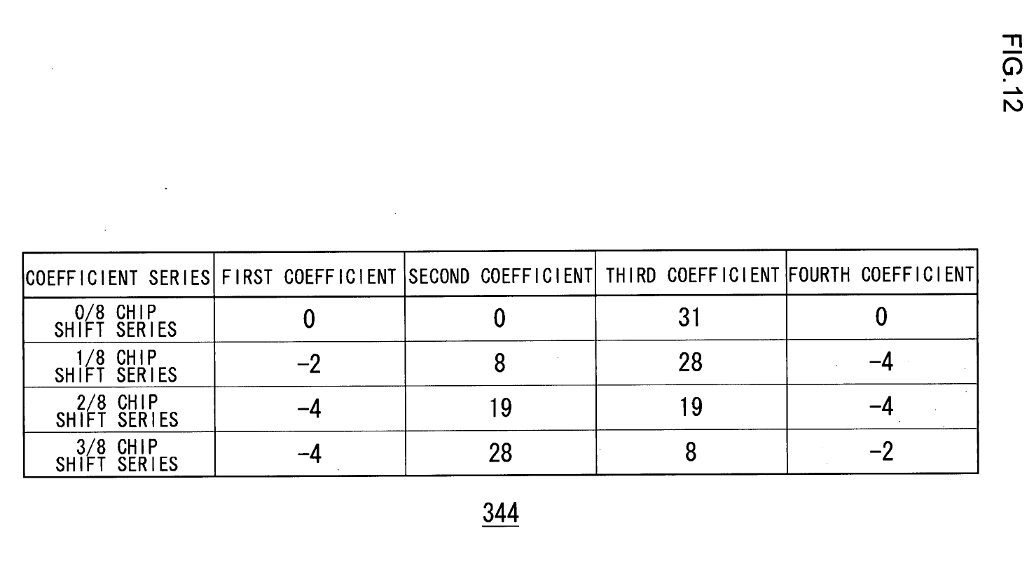

FIG. 12 is a table listing coefficients retained in the coefficient retaining unit 344. For brevity's sake, it is assumed here that the number of delay units 340 is 4 and each of the tap coefficients is defined by 6 bits. The “0/8-chip shift series” is defined so as to fulfill the Nyquist criterion. Therefore, only the third coefficient has a predetermined value and, in this case, a maximum value “31” in 6-bit representation. The other coefficients are defined to be “0”. The “1/8-chip shift series” is shifted by 1/8 chips with respect to the “0/8-chip shift series”. The “2/8-chip shift series” is shifted by 2/8 chips with respect to the “0/8-chip shift series”. The “3/8-chip shift series” is shifted by 3/8 chips with respect to the “0/8-chip shift series”.

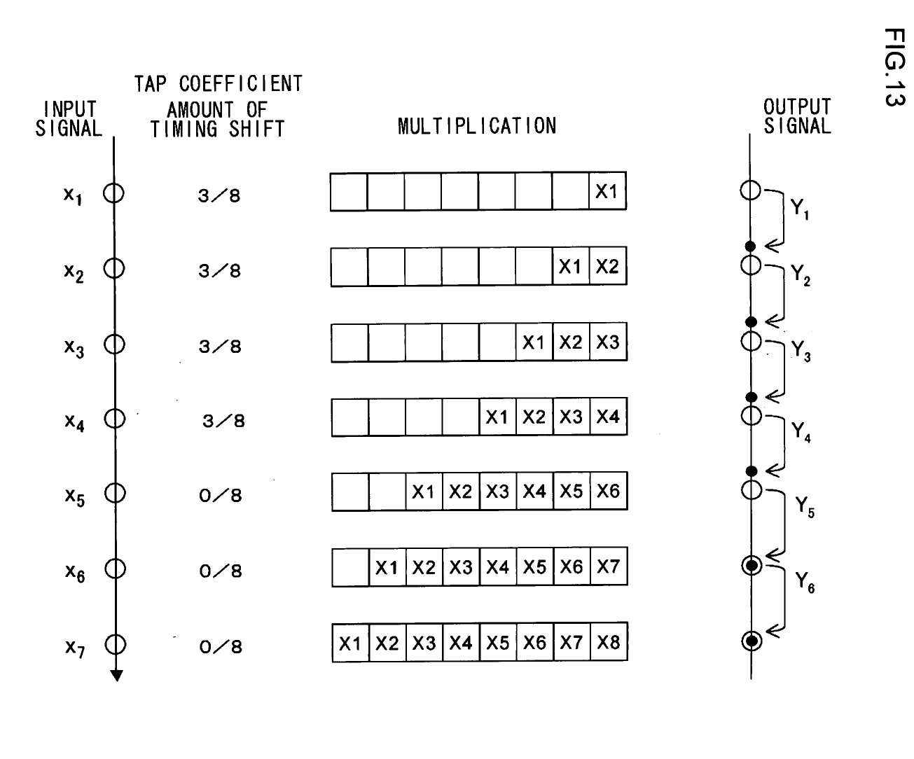

FIG. 13 illustrates the interpolation operation by the interpolation filter 336. The input sample on the left corresponds to the digital received signal 200 input to the interpolation filter 336. Time progresses from top to bottom of the figure. In other words, input samples “X1” through “X6” are received. The interval between the input samples is 1/2 chips. “Tap coefficient/amount of timing shift” denotes the coefficient retained in the coefficient retaining unit 344 selected by the selector unit 352. The amount of timing shift “3/8 chips” corresponds to the “3/8-chip shift series”. The notation “0/8 chips” indicates that the amount of timing shift is 0. Therefore, the timing indicated by “0/8 chips” is identical to the timing of the input signal. The notation “3/8 chips” indicates that the amount of timing shift is 3/8 chips. Therefore, the timing indicated by “3/8 chips” is different from the timing of the input signal.

“Multiplication” indicates the relation between the tap coefficient selected by the selector unit 352 and the digital received signal 200 delayed by the delay units 340. Between the input samples “X1” and “X4”, the shift unit 342 does not change the combination of the digital received signals 200 and the tap coefficients. The digital received signals 200 input to the delay unit 340 are shifted sequentially rightward one by one. When the input sample “X5” arrives, the tap coefficient is changed by 3/8 chips from the “3/8-chip shift series” to the “0/8-chip shift series”. The shift unit 342 changes the combination of the digital received signal 200 and the tap coefficients so as to effect the advancement in the multiplication process by “1/2 chips”. Therefore, the position of “X1” in the multiplication process, occurring when the sample “X5” is input, is shifted leftward by two stages with respect to the position of “X1” occurring when the sample “X4” is input.

“Output signal” in FIG. 13 denotes the filter output signal output 214 from the interpolation filter 336. In the illustration, the timing of the actually output signal is indicated by o and the timing corresponding to the output signal is indicated by ●. For the output signals “Y1” through “Y4”, the timing indicated by the output signal is delayed by 3/8 chips with respect to the timing of the output signal. For the output signals “Y5” and “Y6”, the timing indicated by the output signal is delayed by 1/2 chips with respect to the timing of the output signal.

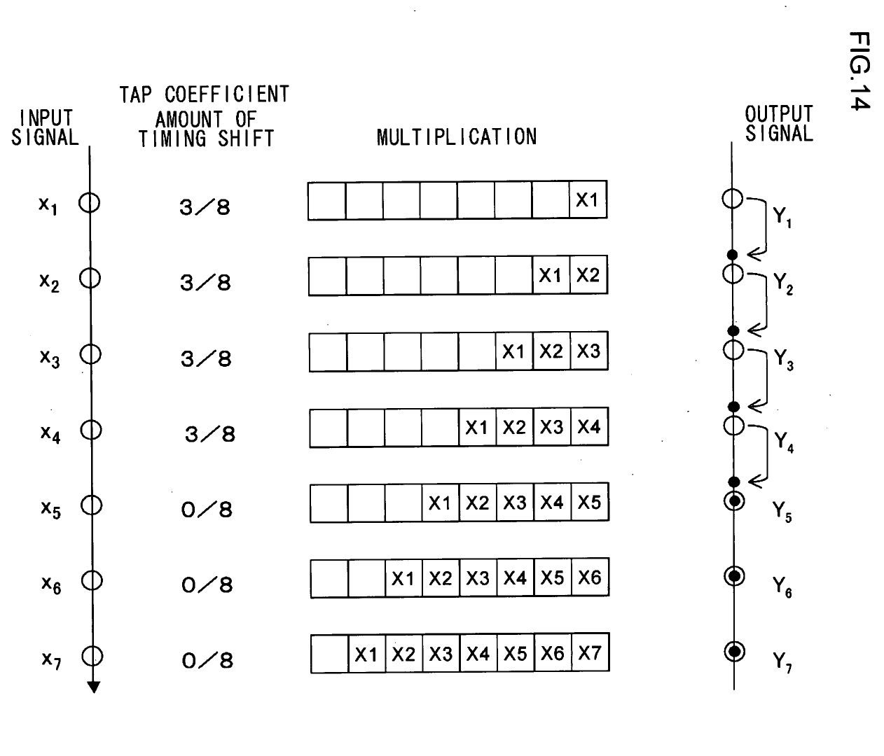

FIG. 14 illustrates the interpolation operation of the interpolation filter 336. Illustrated here is a case where it is necessary to change the combination of the digital received signals 200 and the tap coefficients but the shift unit 342 is incapable of the change. In other words, FIG. 14 shows a case where a need arises to shift the first multiplier unit 346a rightward when the first delay unit 340a and the first multiplier unit 346a are already combined. It will be understood that FIG. 13 illustrates a basic operation and the operation of FIG. 14 addresses a special case not covered by FIG. 13. The operation proceeds in the same manner as in FIG. 13 until the sample “X4” is input. When the sample “X5” is input, the selector unit 352 delays the tap coefficient by “3/8 chips” from the “3/8-chip shift series” to the “0/8-chip shift series”. The shift unit 342 does not change the combination. Therefore, the timing corresponding to the output signal “Y5” is delayed by “1/2 chips” with respect to the timing of the output signal “Y5”. Subsequently, the tap coefficients for the input samples “X6” and “X7” are unchanged and the combination of the digital received signals 200 and the tap coefficients are unchanged.

In the case as described above, the selector unit 352 in the interpolation filter 336 changes the tap coefficient only and allows the unnecessary signal “Y5” to be output. The FWT computation unit 50, etc. in a subsequent stage are capable of processing for demodulation without the output signal “Y5”. The interpolation unit 336 notifies the FWT computation 50, etc. in the subsequent stage of the fact that the unnecessary signal “Y5” is output, using a predetermined means. Details of this will be described later.

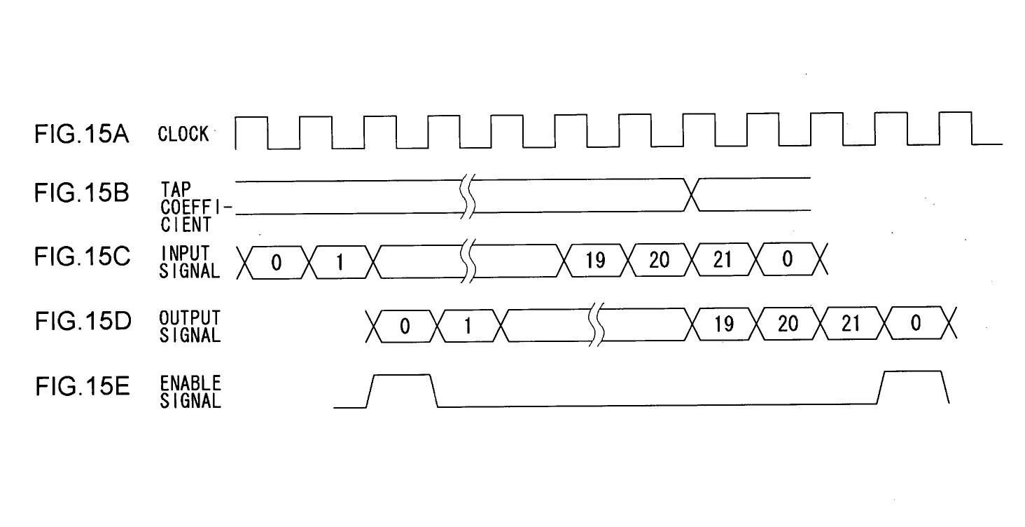

FIGS. 15A-15E are charts illustrating the timing of operation of the interpolation filter 336. FIG. 15A illustrates a 22 MHz clock input to the interpolation filter 336. FIG. 15B illustrates tap coefficients selected by the selector 352. Selection of the tap coefficient is changed in the middle of the illustrated period. FIG. 15C illustrates the input signal input to the multiplier unit 346. The 22 signals indicated by “0” through “21” constitute a symbol, i.e., a CCK modulation unit. The selector unit 352 changes the tap coefficient before the signal “20” ends. The FWT computation unit 50 and the like in the subsequent stage use the 11 signals other than odd-numbered signals, i.e., uses the signals indicated by “0”, “2”, . . . , “20”. Therefore, the change occurs at a border at the end of a symbol, considering the FWT computation unit 50 and the like in the subsequent stage.

It will be assumed here that the shift unit 342 also changes the combination at the above timing, the illustration of the change being omitted from the chart. In an alternative approach, the selector unit 352 may change the selection of tap coefficient, and the shift unit 342 may change the combination, when the signal “21” ends. The requirement of the invention is that changes be made in the selector unit 352 and the shift unit 342 at the timing corresponding to the border of a symbol. FIG. 15D illustrates the output signal output from the interpolation filter 336. A delay from the internal process in the interpolation filter 336 is applied to the output signal. The illustrated delay applied derived from the internal process is only an example. FIG. 15E illustrates an enable signal output from a signal line (not shown) in order to inform the FWT computation unit 50 and the like in the subsequent stage of the head of a symbol. The FWT computation unit 50 and the like in the subsequent stage refers to the enable signal to recognize the period started by the enable signal and including the 22 signals as one symbol. Alternatively, the FWT computation 50 unit and the like recognize the 11 signals following the enable signal and occurring at every other time position as constituting one symbol.

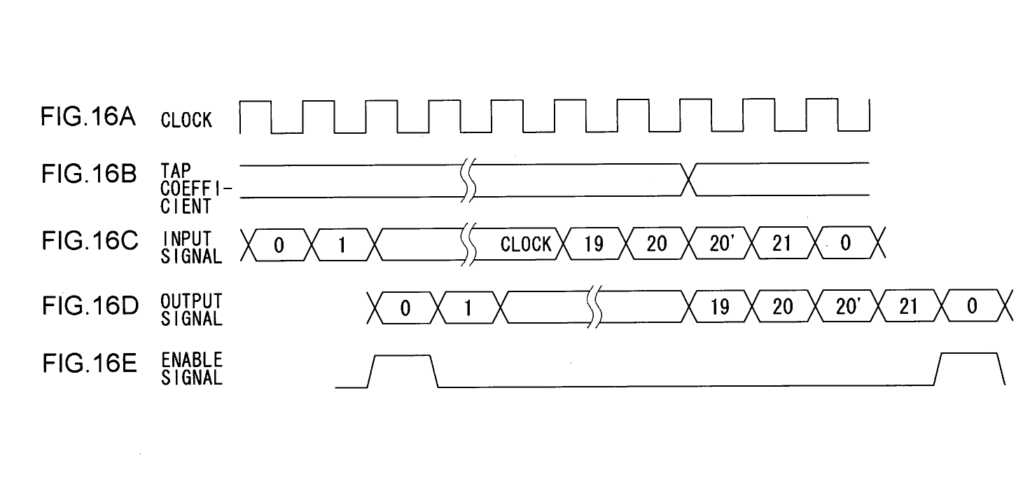

FIGS. 16A-16E are charts illustrating the timing of operation of the interpolation filter 336. FIGS. 16A-16E correspond to FIGS. 15A-15E, respectively, but illustrated here is a case like that of FIG. 14, where it is necessary to change the combination of the digital received signals 200 and the tap coefficients but the shift unit 342 is incapable of the change. The description of the charts of FIGS. 15A-15B also applies to FIGS. 16A-16B. FIGS. 16C illustrate the input signal input to the multiplier unit 346. As in the case of FIG. 14C, the signal “20” unnecessary for the FWT computation unit 50 ant the like in the subsequent stage is output. The relation between FIGS. 16B and 16C is the same as the relation between FIGS. 15B and 15C. The selector unit 352 changes the tap coefficient before the signal “20” ends. The FWT computation unit 50 and the like in the subsequent stage use the 11 signals other than odd-numbered signals, i.e., uses the signals indicated by “0”, “2”, . . . ., “20”. Therefore, the change occurs at a border at the end of a symbol, considering the FWT computation unit 50 and the like in the subsequent stage. The description of the chart of FIG. 15D also applies to FIG. 16D. FIG. 16E illustrates an enable signal output in order to inform the FWT computation unit 50 and the like in the subsequent stage of the head of a symbol. The FWT computation unit 50 and the like in the subsequent stage refer to the enable signal and recognize the 11 signals following the enable signal and occurring at every other time position as constituting one symbol. With this, the unnecessary signal “20′” is eliminated from the process.

A description will now be given of the operation of the demodulation unit 26 with the above-described structure. In time intervals for the preamble and the header, the correlator 44 despreads the signal equalized by the equalizer 42. The PSK demodulation unit 46 demodulates the resultant signal so as to allow the switch unit 60 to output the output signal 202. The first phase error detection unit 48 detects a phase error from the demodulated signal 204. The first phase rotation unit 130 corrects the phase of the filter output signal 214 in accordance with the phase error thus detected. In an interval for the data, the interpolation filter 336 corrects the timing error in the digital received signal 200 in accordance with the timing control signal 216 and outputs the corrected signal to the equalizer 42. The second phase rotation unit 132 corrects the phase error in the signal input from the equalizer 42 in accordance with the phase correction signal 220.

The second phase error detection unit 56 outputs the timing control signal 216 and the phase correction signal 220 by referring to the rotated signal 218 input from the second phase rotation unit 132. The FWT computation unit 50 subjects the signal input from the second phase rotation unit 132 to FWT computation so as to determine Walsh transform values FWT. The maximum value searching unit 52 determines the magnitude of Walsh transform value FWT as a sum of absolute values, and outputs a combination of φ2 through φ4 corresponding to the largest Walsh transform value FWT. The φ1 demodulation unit 54 outputs φ1.

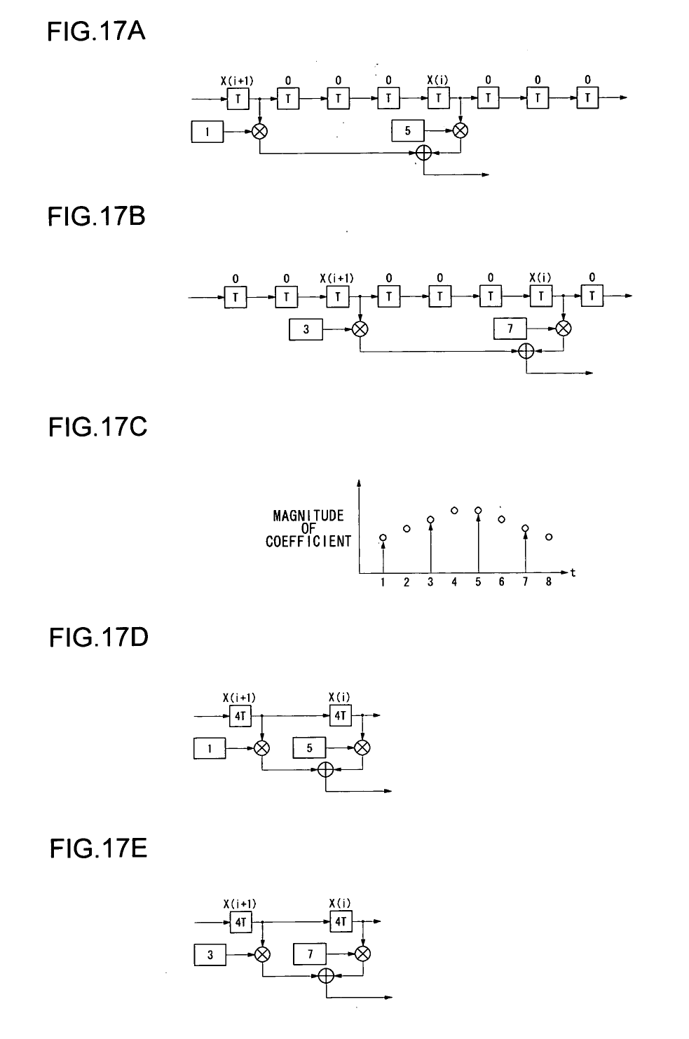

FIGS. 17A-17E illustrate the operating principle of the interpolation filter 336 according to a variation of the example. In the interpolation filter 336 that has been described above, the sampling rate in the filter output signal 214 is prescribed to be the identical to the sampling rate of the digital received signal 200. In the variation, however, the sampling rate of the filter output signal 214 is prescribed to be faster than the sampling rate of the digital received signal 200. For example, the sampling rate of the filter output signal 214 is prescribed to be twice the sampling rate of the digital received signal 200. FIG. 17A is not related to the inventive example but illustrates the process performed by a conventional interpolation filter for converting into a fast sampling rate. In a similar way to FIGS. 1A-11D, the operating principle of the interpolation filter 336 according to the variation will be explained by explaining the operating principle of a conventional interpolation filter. FIG. 17A is the same as FIG. 11A so that the description thereof is omitted. FIG. 17B illustrates a state advanced in time by two samples from the state of FIG. 17A. FIG. 17C illustrates the magnitude of tap coefficients for effective valid multiplication in FIGS. 17A and 17B.

FIGS. 17D and 17E correspond to FIGS. 17A and 17B, respectively, where a tap delay time is changed from “T” to “4T”. The time “4T” corresponds to the interval of sampling in the AD unit 324 of FIG. 2. That is, the taps “4T” in FIGS. 17D and 17E correspond to the delay units 340 of FIG. 5. As illustrated, a difference between FIGS. 17D and 17E consists in the value of tap coefficient used for multiplication. X(i) and X(i+1) retained in the taps “4T” remain unchanged. More specifically, while the digital received signal 200 input to the delay unit 340 maintains its value therein, the selector unit 352 switches between tap coefficients retained in the coefficient retaining unit 344 and outputs the selected coefficient to the multiplier unit 344, the number of times of switching being commensurate with a ratio between the sampling rate of the filter output signal 214 and the sampling rate of the digital received signal 200. The multiplication unit 346 performs multiplication every time the tap coefficient selected by the selector unit 352 is changed. The adder unit 348 also performs addition every time the multiplication is performed. As a result, the adder unit 348 outputs the filter output signal 214 having a sampling rate faster than the sampling rate of the digital received signal 200.

The tap coefficients retained in the coefficient retaining unit 344 may be those that correspond to the sampling rate required of the filter output signal 214. The coefficient retaining unit 344 may retain a plurality of candidates corresponding to a sampling rate equal to or greater than the least common multiple of the sampling rate required of the filter output signal 214 and the sampling rate of the digital received signal 200. For example, when the output of the filter output signal 214 with a sampling rate twice as fast as the sampling rate of the digital received signal 200 is desired, the coefficient retaining unit 344 may retain tap coefficients corresponding to a sampling rate four times as fast as the sampling rate of the digital received signal 200. By retaining these coefficients, the precision of the output signal is improved.

A description will be given below of another variation of the interpolation operation of the interpolation filter 336 described by referring to FIGS. 13 and 14. Referring to FIGS. 13 and 14, the timing indicated by the output signal, i.e., the timing indicated by the coefficients retained in the coefficient retaining unit 344, is delayed by “3/4 chips” with respect to the timing of the output signal. The following description pertains to a case where the timing indicated by the output signal, i.e., the timing indicated by the coefficients retained in the coefficient retaining unit 344, is advanced by “3/4 chips” with respect to the timing of the output signal.

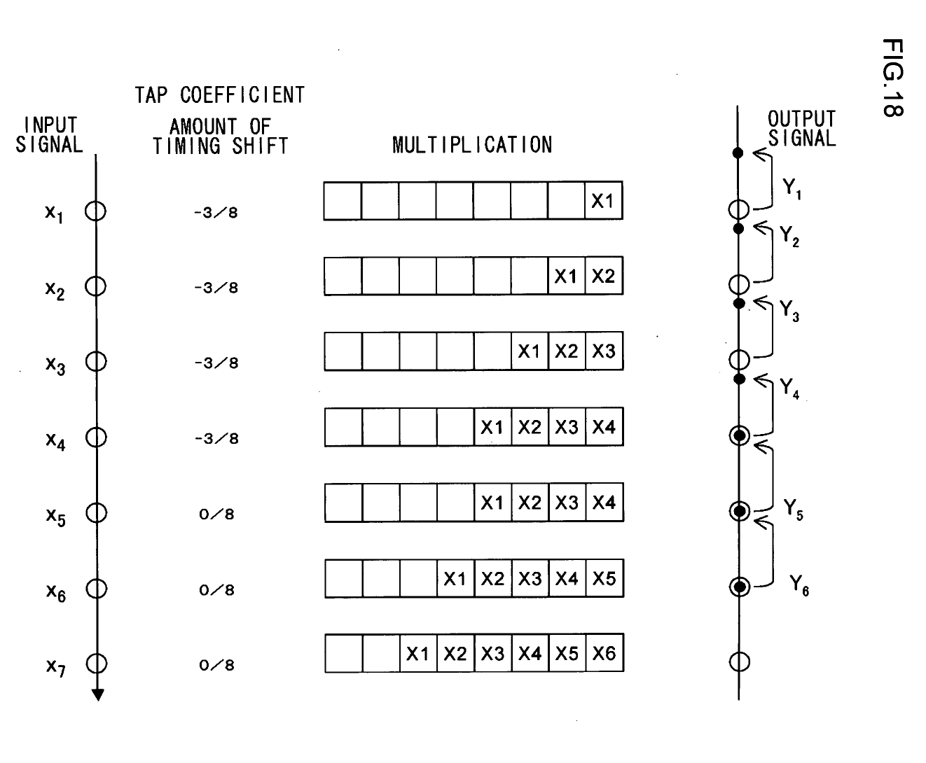

FIG. 18 illustrates an alternative interpolation operation by the interpolation filter 336. FIG. 18 corresponds to FIG. 13. The input samples of FIG. 18 are identical to the input samples of FIG. 13. The amount of timing shift of FIG. 18 is “−3/8 chips”, which is different from the amount of FIG. 13. “Multiplication” indicates the relation between the tap coefficients selected by the selector 352 and the digital received signals 200 delayed by the delay units 340. Between the input samples “X1” and “X4”, the digital received signals 200 input to the delay units 340 are the same as the corresponding signals of FIG. 13. However, the amount of timing shift in each of the tap coefficients of FIG. 18 differs from that of FIG. 13. For the output signals “Y1” through “Y4”, the timing indicated by the output signal is advanced by 3/8 chips with respect to the timing of the output signal.

When the input sample “X5” is input, the tap coefficient is changed from the “−3/8-chip shift series” to the “0/8-chip shift series”. The shift unit 342 delays the combination of the digital received signals 200 and the tap coefficients by “1/2 chips”. As a result of this, when the input sample “X5” is input, the timing of the digital received signal 200 input to the delay unit 340 is identical to the timing thereof occurring when the input sample “X4” is input. Consequently, for the output signals “Y5” and “Y6”, the timing indicated by the output signal is advanced by 4/8 chips with respect to the timing of the output signal.

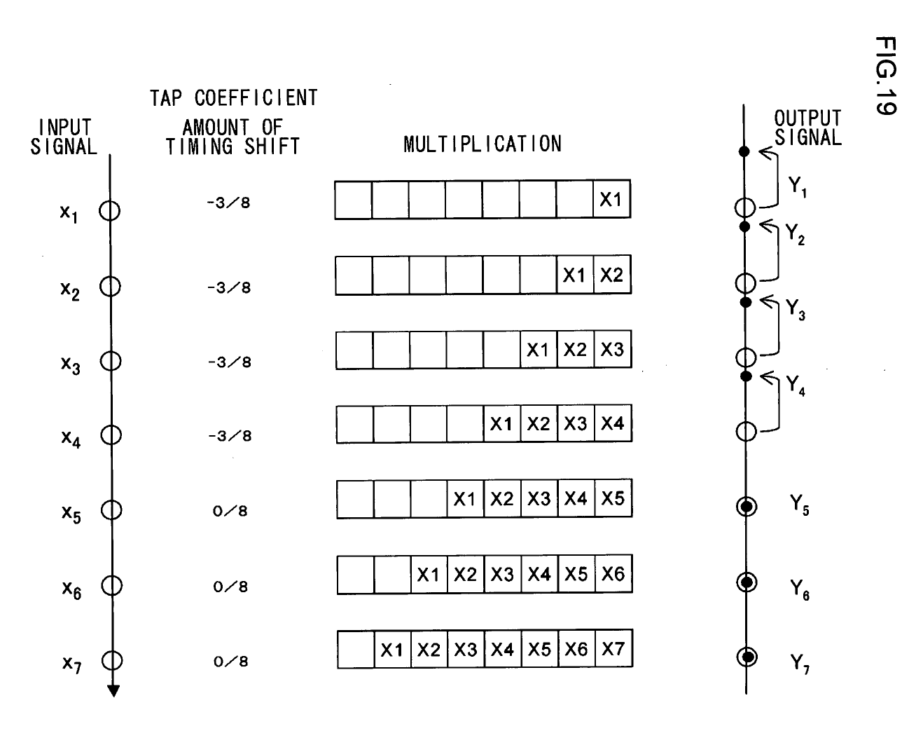

FIG. 19 illustrates another alternative interpolation operation by the interpolation filter 336. FIG. 19 illustrates a case where it is necessary to change the combination of the digital received signals 200 and the tap coefficients but the shift unit 342 is incapable of the change. In other words, FIG. 19 shows a case where a need arises to shift the Mth multiplier unit 346m leftward when the Nth delay unit 340n and the Mth multiplier unit 346m are already combined. It will be understood that FIG. 18 illustrates a basic operation and the operation of FIG. 19 addresses a special case not covered by FIG. 18. The operation up to the input sample “X4” is the same as the corresponding operation of FIG. 18. When the input sample “X5” is input, the selector unit 352 switches the tap coefficient to “−3/8-chip shift series” to “0/8-chip shift series”. The shift unit 342 does not change the combination. Therefore, the timing corresponding to the output signal “Y5” is identical to the timing corresponding to the input sample “X5”. Therefore, the output signal corresponding to the timing of the input sample “X4” is skipped. Subsequently, for the input samples “X6” and “X7”, the tap coefficients are not changed, and the combination of the digital received signals 200 and the tap coefficients is not changed.

That is, in the case as described above, the selector unit 352 of the interpolation filter 336 only changes the tap coefficient and skips the signal “Y5” corresponding to the input sample “X4”. The FWT computation unit 50, etc. in the subsequent stage are capable of processing for demodulation without the skipped signal. More specifically, the FWT computation unit 50, etc. uses signals at chip intervals. Thus, of those signals at 1/2 chip intervals, those signals other than the skipped signal are used. The interpolation unit 336 notifies the FWT computation 50, etc. in the subsequent stage of the fact that the signal is skipped, using a predetermined means (not shown).

According to the example of the present invention, a plurality of combinations each comprising a plurality of tap coefficients are retained, the plurality of combinations corresponding to a plurality of timings. One of the combinations is selected to perform a filtering process in accordance with a direction. With this, the number of taps and the circuit scale are prevented from being increased even in an configuration in which an output signal is obtained by shifting input signals in time. Since the circuit scale is prevented from being increased, power consumption is suppressed. Timing adjustment is performed not only by chancing the tap coefficient but also by changing the combination of signals multiplied and the tap coefficients. Therefore, the range of timing adjustment is extended while preventing the circuit scale from being increased. Further, even when the combination of the signals to be multiplied and the tap coefficients cannot be changed, an unnecessary signal is temporarily output and the demodulation unit in the subsequent stage is informed of the output of the unnecessary signal. Therefore, the failure to change is addressed properly without affecting the demodulation process in the subsequent stage. By suspending the output of signals temporarily and notifying the demodulation unit in the subsequent stage of the suspension of the signal output when the combination of the signals to be multiplied and the tap coefficients cannot be changed, the failure to change is addressed without affecting the demodulation process in the subsequent stage.

Since timing adjustment is performed symbol by symbol, the demodulation process in the subsequent stage is not affected. Since the number of taps is not increased in outputting a signal at a sampling rate higher than the sampling rate of the input signal. Accordingly, the circuit scale is prevented from being increased. By using tap coefficient values that correspond to a high sampling rate, the precision of the output signal is improved. Since the absolute phase of the received signal is corrected in advance, the phase error and the timing error in the received signal are estimated by referring to the phase error between the corrected phase and the phase to which the received signal is to be assigned. Since the absolute phase of the received signal is corrected in advance, the precision in estimating the timing error is increased by subjecting to a statistical process the variance of errors between the corrected phase and the phase to which the signal is to be assigned.

Described above is an explanation based on the example. The example is only illustrative in nature and it will be obvious to those skilled in the art that variations in constituting elements and processes are possible within the scope of the present invention.

The coefficient retaining unit 344 in the example retains the tap coefficients corresponding to all timings that should be covered. Alternatively, the coefficient retaining unit may not retain tap coefficients corresponding to the “0/8-chip shift series”. In the “0/8-chip shift series”, one of the tap coefficients has a predetermined value and the other are of a 0 value. Thus, when the designated amount of timing shift is “0/8 chips”, the digital received signal 200 corresponding to the one tap having the predetermined value may be output to the multiplier unit 346 and the other digital received signals 200 corresponding to the other taps may not be output to the multiplier unit 346. According to the variation described above, the processing is simplified since unnecessary processes are not executed. What is required is that the timing of the output signal is adjusted in accordance with the value of the tap coefficient.

In the example of the present invention, the demodulation unit 26 demodulates the spread spectrum signal and the second error detection unit 56 estimates the phase error and the timing error by referring to the phase error of the CCK modulated signal. Alternatively, a single-carrier signal not spectrum spread or a multi-carrier signal may be the target of processing. The single-carrier signal and the multi-carrier signal are also assigned to predetermined phases in a phase plane. The second error detection unit 56 estimates the phase error and the timing error, as described in the example above. According to the variation described above, the present invention is applicable to various communication systems. The requirement here is that constellation points are assigned to predetermined phases.

In the example of the present invention, the approximation unit 112 determines an approximate value R of the magnitude of the Walsh transform value FWT as a sum of absolute values. Alternatively, the approximate value R of the magnitude of the Walsh transform FWT may be determined as given below.
R=Max{|I|, |Q|}+0.5×Min{|I|, |Q|}

Alternatively, the approximate value R may be determined as follows.
R=Max{|I|, |Q|}+k×Min{|I|, |Q|}
where k indicates a constant. Alternatively, the an error between the phase of the Walsh transform value FWT and one of the phases to which the Walsh codes are assigned may be calculated. A coefficient may be calculated such that, as the error becomes smaller, the magnitude of the coefficient is larger accordingly. The coefficient is multiplied by a square sum of I and Q of the Walsh transform values FWT, so as to determine the approximate value R. According to a variation described above, the receiving performance is improved. The point here is that, the closer the phase of the Walsh transform value FWT to the phase to which the Walsh code is assigned, the larger the magnitude of the approximate value R.

In the example of the present invention, the first phase rotation unit 130 and the second phase rotation unit 132 only correct the phase error of the received signal. In an alternative approach, frequency error as well as phase error may be corrected. According to this variation, the required range for detecting the phase error is reduced and the precision in detecting the phase error is increased, thereby improving the receiving performance. The requirement here is that the phase error in the received signal is corrected.

Although the present invention has been described by way of exemplary embodiments, it should be understood that many changes and substitutions may further be made by those skilled in the art without departing from the scope of the present invention which is defined by the appended claims.

1. A digital filter comprising:
an input unit which receives input sampled data at predetermined timings;
a delay unit which sequentially delays the input data using a plurality of taps;
a managing unit which manages a plurality of coefficients to be multiplied by a plurality of data items sequentially delayed by said plurality of taps;
a multiplier unit which multiplies the plurality of data items sequentially delayed by the plurality of taps by the plurality of coefficients; and an adder which adds up multiplied data, wherein
the managing unit retains, for each of the plurality of coefficients, a plurality of candidate coefficients corresponding to the plurality of timings of sampling, and switches between timings of sampling corresponding to added data produced by the adder, by switchably selecting one of the plurality of candidate coefficients retained.

2. The digital filter according to claim 1, wherein the sampling rate of the added data produced by the adder is prescribed to be practically identical to the sampling rate of the input data received by the input unit, and wherein the plurality of candidate coefficients retained by the managing unit include a value corresponding to a predetermined timing and values corresponding to timings shifted with respect to the predetermined timing based on a tap interval.

3. The digital filter according to claim 1, further comprising a shift unit which switches between combinations of the plurality of data items and the plurality of coefficients to be multiplied by each other in the multiplier unit.

4. The digital filter according to claim 2, further comprising a shift unit which switches between combinations of the plurality of data items and the plurality of coefficients to be multiplied by each other in the multiplier unit.

5. The digital filter according to claim 3, further comprising:
an accepting unit which accepts a timing of sampling required of the added data produced by the adder; and
a control unit which directs the shift unit to switch the combination and directs the managing unit to switch the selection, in accordance with the accepted timing.

6. The digital filter according to claim 4, further comprising:
an accepting unit which accepts a timing of sampling required of the added data produced by the adder; and
a control unit which directs the shift unit to switch the combination and directs the managing unit to switch selection, in accordance with the accepted timing.

7. The digital filter according to claim 5, wherein,
when a switch between combinations in the shift unit is necessary and the shift unit is not capable of the switch, the control unit causes the adder unit to output data not necessary for a processor provided in a stage subsequent to the adder, by causing the managing unit to switch selection, and wherein
the control unit comprises a notification unit which notifies the processor of the output of the unnecessary data from the adder.

8. The digital filter according to claim 6, wherein,
when a switch between combinations in the shift unit is necessary and the shift unit is not capable of the switch, the control unit causes the adder unit to output data not necessary for a processor provided in a stage subsequent to the adder, by causing the managing unit to switch selection, and wherein
the control unit comprises a notification unit which notifies the processor of the output of the unnecessary data from the adder.

9. The digital filter according to claim 5, wherein,
when a switch between combinations in the shift unit is necessary and the shift unit is not capable of the switch, the control unit skips at least one data item to be output from the adder to a processor provided in a stage subsequent to the adder, by causing the managing unit to switch selection, and wherein
the control unit comprises a notification unit which notifies the processor when at least one data item to be output from the adder is skipped.

10. The digital filter according to claim 6, wherein,
when a switch between combinations in the shift unit is necessary and the shift unit is not capable of the switch, the control unit skips at least one data item to be output from the adder to a processor provided in a stage subsequent to the adder, by causing the managing unit to switch selection, and wherein
the control unit comprises a notification unit which notifies the processor when at least one data item to be output from the adder is skipped.

11. The digital filter according to claim 5, wherein
the data input to the input unit comprises a plurality of data items constituting a group, and wherein
the control unit directs the shift unit to switch between combinations and directs the managing unit to switch selection, at a timing corresponding to the end of the group.

12. The digital filter according to claim 6, wherein
the data input to the input unit comprises a plurality of data items constituting a group, and wherein
the control unit directs the shift unit to switch between combinations and directs the managing unit to switch selection, at a timing corresponding to the end of the group.

13. The digital filter according to claim 7, wherein
the data input to the input unit comprises a plurality of data items constituting a group, and wherein
the control unit directs the shift unit to switch between combinations and directs the managing unit to switch selection, at a timing corresponding to the end of the group.

14. The digital filter according to claim 8, wherein
the data input to the input unit comprises a plurality of data items constituting a group, and wherein
the control unit directs the shift unit to switch between combinations and directs the managing unit to switch selection, at a timing corresponding to the end of the group.

15. The digital filter according to claim 9, wherein
the data input to the input unit comprises a plurality of data items constituting a group, and wherein
the control unit directs the shift unit to switch between combinations and directs the managing unit to switch selection, at a timing corresponding to the end of the group.

16. The digital filter according to claim 10, wherein
the data input to the input unit comprises a plurality of data items constituting a group, and wherein
the control unit directs the shift unit to switch between combinations and directs the managing unit to switch selection, at a timing corresponding to the end of the group.

17. The digital filter according to claim 1, wherein
the sampling rate of the added data produced by the adder is prescribed to be higher than the sampling rate of the input data input to the input unit,
the managing unit switches between plurality of coefficients retained while the plurality of data items sequentially delayed by the plurality of taps maintain constant values, the number of times of switching being commensurate with a ratio between the sampling rate of the added data produced by the adder and the sampling rate of the input data input to the input unit,
the multiplier unit executes multiplication on the plurality of data items maintaining constant values the same number of times commensurate with the ratio, and
the adder executes addition the same number of times commensurate with the ratio.

18. The digital filter according to claim 17, wherein the managing unit retains the plurality of candidate coefficients having values corresponding to a sampling rate equal to or greater than the least common multiple of the sampling rate of the added data produced by the adder and the sampling rate of the input data input to the input unit.

19. A receiver comprising:
an input unit which receives input sampled data at predetermined timings;
a delay unit which sequentially delays the input data using a plurality of taps;
a managing unit which manages a plurality of coefficients to be multiplied by a plurality of data items sequentially delayed by said plurality of taps;
a multiplier unit which multiplies the plurality of data items sequentially delayed by the plurality of taps by the plurality of coefficients;
an adder which adds up multiplied data; and
a demodulation unit which demodulates added data, wherein
the managing unit retains, for each of the plurality of coefficients, a plurality of candidate coefficients corresponding to a plurality of timings of sampling, and switches between timings of sampling corresponding to added data produced by the adder, by switchably selecting one the plurality of candidate coefficients retained.

20. A timing adjustment method comprising the steps of:
multiplying a plurality of data items obtained by sequentially delaying data sampled at predetermined timings by a plurality of taps, by a plurality of coefficients;
retaining, for each of the plurality of coefficients, a plurality of candidate coefficients corresponding to a plurality of timings of sampling;
switchably selecting one of the plurality of candidate coefficients retained, and thereby switching between timings of sampling corresponding to added data produced by the adder.
